(19) United States
(12) Patent Application Publication
(10) Pub. No.: US 2016/0013047 A1
(43) Pub. Date: Jan. 14, 2016

(54) SEMICONDUCTOR SUBSTRATE CLEANING SYSTEM AND METHOD FOR CLEANING SEMICONDUCTOR SUBSTRATE

(71) Applicant: Yuichi OGAWA, Nakano-ku, Tokyo (JP)

(72) Inventor: Yuichi OGAWA, Tokyo (JP)

(73) Assignee: Kurita Water Industries Ltd., Tokyo (JP)

(21) Appl. No.: 14/771,890

(22) PCT Filed: Feb. 28, 2014
(86) PCT No.: PCT/JP2014/055082

§ 371 Date: Sep. 1, 2015

(30) Foreign Application Priority Data
Mar. 1, 2013 (JP) 2013-041179

(51) Int. Cl. H01L 21/02; B08B 3/08; H01L 21/67

(52) U.S. Cl. CPC H01L 21/02068; H01L 21/67051; B08B 3/08

(57) ABSTRACT

There is provided a method for cleaning a semiconductor substrate to remove platinum and/or a platinum alloy from the semiconductor substrate having a layer having Si as its constituting component, and the method enables Al, a silicide film, a Si-based insulating film, a Si-based substrate and the like to be effectively cleaned without being damaged.

The method for cleaning a semiconductor substrate to remove platinum and/or a platinum alloy from the semiconductor substrate having a layer having Si as its constituting component comprises a first cleaning step of bringing the semiconductor substrate into contact with a first solution containing nitric acid and/or hydrogen peroxide as main solutes to thereby clean the semiconductor substrate, and a second cleaning step of bringing the semiconductor substrate having undergone the first cleaning step into contact with a second solution containing an oxidizing agent-containing sulfuric acid solution and a halide and having a temperature of 25 to 100° C., to thereby clean the semiconductor substrate.

### TECHNICAL FIELD

The present invention relates to a method for cleaning and a system for cleaning a semiconductor substrate, in which platinum or a platinum alloy is cleaned and removed from a semiconductor substrate having a layer composed of silicon as its constituting element.

### BACKGROUND ART

In recent years, in transistor forming processes, materials such as Ni and Co are used and the silicidation for forming NiSi, CoSi and the like is carried out, in order to reduce the resistances of sources and drains. Further in order to reduce the junction leak current, alloys in which 5 to 10% of Pt or Pd is adding in Ni or Co are used. Among these, the case of using NiPt is anticipated to make an improvement in the heat resistance and have an effect of suppressing the junction leak current (see Patent Literatures 1 and 2).

In the silicidation step, although an alloy is formed as a film on a Si substrate, and thereafter subjected to a thermal oxidation treatment to allow the alloy and Si to react to thereby form a silicide, the remaining unreacted alloy needs to be removed. There are known, for example, methods in which after a NiPt silicide is formed, an SPM (a mixed solution of sulfuric acid and hydrogen peroxide) is used in order to remove unreacted NiPt (see Patent Literatures 3 and 4). There is known a cleaning method involving using an aqua regia in which while NiPt is being dissolved, etching of Al is suppressed (Patent Literature 5). There is further proposed a method involving carrying out a treatment with a sulfuric acid-based oxidizing agent and thereafter, a treatment with a hydrochloric acid-based oxidizing agent (see Patent Literature 6).

Further for the removal of Pt from Si-based insulating films (SiN, SiO₂ and the like), various types of cleaning agents are proposed. For example, Patent Literature 7 proposes the removal of Pt using a cleaning liquid in which a trace amount of hydrofluoric acid is added as a cleaning liquid, for example, using a hydrochloric acid-hydrogen peroxide-hydrofluoric acid mixed solution; and Patent Literature 8 proposes the removal of Pt using a cleaning liquid in which trace amounts of hydrofluoric acid and a chelate agent are added, for example, using a hydrochloric acid-hydrogen peroxide-hydrofluoric acid-chelate solution.

Further also in the removal of Pt from substrates having Si-based semiconductors (Si semiconductor and Si compound semiconductors such as SiC), various types of cleaning agents are proposed. For example, in Patent Literatures 9 and 10, in order to flatten a SiC substrate, Pt is removed with an aqua regia, or metals and TOC are removed with an SPM.

### CITATION LIST

### Patent Literature

Patent Literature 1: Japanese Patent Laid-Open No. 2008-258487
Patent Literature 2: Japanese Patent Laid-Open No. 2008-160116
Patent Literature 3: Japanese Patent Laid-Open No. 2002-124487
Patent Literature 4: Japanese Patent Laid-Open No. 2008-118088
Patent Literature 5: National Publication of International Patent Application No. 2009-535846
Patent Literature 6: Japanese Patent Laid-Open No. 2010-157684
Patent Literature 7: Japanese Patent Laid-Open No. 2000-100765
Patent Literature 8: Japanese Patent Laid-Open No. 2000-223461
Patent Literature 9: Japanese Patent Laid-Open No. 2009-117782
Patent Literature 10: Japanese Patent Laid-Open No. 2012-064972
Patent Literature 11: Japanese Patent Laid-Open No. 2013-229543

### SUMMARY OF INVENTION

### Problems to be Solved by the Invention

Any conventional methods, however, have the following problems: these methods damage silicides, Si-based insulating films or Si-based substrates; these methods cannot completely remove Pt and Pt alloys; or these methods take a long cleaning time for the complete removal of Pt and Pt alloys.

For example, in a method involving using an SPM, if the blend ratio of hydrogen peroxide is raised, NiPt can be dissolved. But, at the same time a substrate, which should not be damaged, is damaged, and Al and the like, which should not be etched, are dissolved.

Further, a method involving using an aqua regia results in damaging a substrate and dissolving Al, which should not be etched since the hydrochloric acid concentration is high.

Further also a method involving carrying out a treatment with a sulfuric acid-based oxidizing agent and thereafter a treatment with a hydrochloric acid-based oxidizing agent results in damaging a substrate, since the hydrochloric acid concentration is high as in an aqua regia.

Then, Patent Literature 11 proposes an electrolytic solution hydrochloric acid as a cleaning agent to selectively remove NiPt being a silicidation residue of a TiN-exposed substrate. However, even the use of the cleaning agent leaves the following problems.

1) When Pt on a Si-based insulating film is removed, the Si-based insulating film is excessively etched in some cases.
2) When Pt on a Si-based substrate is removed, a long cleaning time is needed in order to completely remove Pt.
3) When a Pt alloy of a silicidation residue on a Si substrate is removed, a long time is needed for complete removal thereof, and besides, in the case where Al is exposed, Al is sometimes excessively etched.

The present invention has been achieved in consideration of the above situation, and has an object to provide a method for cleaning and a system for cleaning a semiconductor, in which when the semiconductor substrate having a layer having Si as its constituting component is cleaned, platinum and/or a platinum alloy can effectively be cleaned and removed without damaging the substrate and the like.

### Means for Solving the Problems

That is, in the method for cleaning a semiconductor substrate according to the present invention, the first aspect of the present invention is a method for cleaning a semiconductor substrate to remove platinum and/or a platinum alloy from the semiconductor substrate having a layer having Si as a constituting element thereof, the method comprising:

a first cleaning step of bringing the semiconductor substrate into contact with a first solution containing nitric acid and/or hydrogen peroxide as main solutes to thereby clean the semiconductor substrate; and

a second cleaning step of bringing the semiconductor substrate having undergone the first cleaning step into contact with a second solution containing an oxidizing agent-containing sulfuric acid solution and a halide and having a temperature of 25 to 100° C., to thereby clean the semiconductor substrate.

A method for cleaning a semiconductor substrate according to the second aspect of the present invention is a method in which in the first aspect of the present invention, the semiconductor substrate is any one of a semiconductor substrate having an insulating film constituted of a Si compound, a semiconductor substrate constituted of Si or a Si compound semiconductor, and a semiconductor substrate having a silicide film.

A method for cleaning a semiconductor substrate according to the third aspect of the present invention is a method in which in the first or second aspect of the present invention, the semiconductor substrate has a silicide film containing platinum formed thereon.

A method for cleaning a semiconductor substrate according to the fourth aspect of the present invention is a method in which in any one of the first to third aspects of the present invention, the semiconductor substrate has Al present thereon.

A method for cleaning a semiconductor substrate according to the fifth aspect of the present invention is a method in which in any one of the first to fourth aspects of the present invention, the semiconductor substrate has SiO₂ and platinum and/or a platinum alloy exposed thereon.

A method for cleaning a semiconductor substrate according to the sixth aspect of the present invention is a method in which in any one of the first to fifth aspects of the present invention, the semiconductor substrate is a SiC substrate having platinum and/or a platinum alloy exposed thereon.

A method for cleaning a semiconductor substrate according to the seventh aspect of the present invention is a method in which in any one of the first to sixth aspects of the present invention, the semiconductor substrate is a SiGe substrate having platinum and/or a platinum alloy exposed thereon.

A method for cleaning a semiconductor substrate according to the eighth aspect of the present invention is a method in which in any one of the first to seventh aspects of the present invention, the halide comprises one or more selected from the group consisting of chlorides, bromides and iodides.

A method for cleaning a semiconductor substrate according to the ninth aspect of the present invention is a method in which in any one of the first to eighth aspects of the present invention, the first solution contains 80% or more in mass ratio of nitric acid and/or hydrogen peroxide with respect to the whole solutes.

A method for cleaning a semiconductor substrate according to the tenth aspect of the present invention is a method in which in any one of the first to ninth aspects of the present invention, the first solution contains nitric acid, and has a nitric acid concentration of 1 to 60% by mass.

A method for cleaning a semiconductor substrate according to the eleventh aspect of the present invention is a method in which in any one of the first to tenth aspects of the present invention, the first solution contains hydrogen peroxide, and has a hydrogen peroxide concentration of 1 to 35% by mass.

A method for cleaning a semiconductor substrate according to the twelfth aspect of the present invention is a method in which in the eleventh aspect of the present invention, the hydrogen peroxide concentration is 2 to 35% by mass.

A method for cleaning a semiconductor substrate according to the thirteenth aspect of the present invention is a method in which in any one of the first to twelfth aspects of the present invention, the first solution in the first cleaning step has a temperature of 25 to 100° C.

A method for cleaning a semiconductor substrate according to the fourteenth aspect of the present invention is a method in which in any one of the first to thirteenth aspects of the present invention, the second solution has a sulfuric acid concentration of 40 to 80% by mass.

A method for cleaning a semiconductor substrate according to the fifteenth aspect of the present invention is a method in which in any one of the first to fourteenth aspects of the present invention, the second solution has an oxidizing agent concentration of 0.001 to 2 mol/L.

A method for cleaning a semiconductor substrate according to the sixteenth aspect of the present invention is a method in which in any one of the first to fifteenth aspects of the present invention, the oxidizing agent is persulfuric acid.

A method for cleaning a semiconductor substrate according to the seventeenth aspect of the present invention is a method in which in any one of the first to sixteenth aspects of the present invention, the oxidizing agent-containing sulfuric acid solution of the second solution is one or more selected from the group consisting of sulfuric acid electrolytic solutions, mixed solutions of sulfuric acid and hydrogen peroxide, and mixed solutions of sulfuric acid and ozone.

A method for cleaning a semiconductor substrate according to the eighteenth aspect of the present invention is a method in which in any one of the first to seventeenth aspects of the present invention, the method further comprises, before the second cleaning step, a first solution discharge step of discharging the first solution from the semiconductor substrate having undergone the first cleaning step.

A system for cleaning a semiconductor substrate according to the nineteenth aspect of the present invention is a system comprising:

a cleaning section carrying out cleaning to remove platinum and/or a platinum alloy from the semiconductor substrate having a layer having Si as a constituting element thereof;

a first solution-accommodating section accommodating a first solution containing nitric acid and/or hydrogen peroxide as main solutes;

a second solution-accommodating section accommodating a second solution containing an oxidizing agent-containing sulfuric acid solution and a halide;

a first solution supply line having one end thereof connected to the first solution-accommodating section and the other end thereof connected to the cleaning section, and supplying the first solution from the first solution-accommodating section to the cleaning section;

a second solution supply line having one end thereof connected to the second solution-accommodating section and the other end thereof connected to the cleaning section, and supplying the second solution from the second solution-accommodating section to the cleaning section;

a first solution temperature-regulating section provided on the first solution supply line and regulating the solution temperature of the first solution supplied to the cleaning section through the first solution supply line at a predetermined temperature;

a first solution delivery section connected to the end on the cleaning section side of the first solution supply line and delivering the first solution in the cleaning section to thereby bring the first solution into contact with the semiconductor substrate; and

a second solution delivery section connected to the end on the cleaning section side of the second solution supply line and delivering the second solution in the cleaning section to thereby bring the second solution into contact with the semiconductor substrate.

A system for cleaning a semiconductor substrate according to the twentieth aspect of the present invention is a system in which in the nineteenth aspect of the present invention, the system further comprises a cleaning control section controlling the supplies of the first solution and the second solution to carry out the first cleaning step of carrying out cleaning of the semiconductor substrate by using the first solution in the cleaning section and to carry out, after the first cleaning step, the second cleaning step of carrying out cleaning of the semiconductor substrate by using the second solution in the cleaning section.

Hereinafter, the present invention will be described in detail.

The first solution to be used in the present invention contains nitric acid and/or hydrogen peroxide as main solutes. Either one thereof can be used, or both thereof can be mixed. In the case where both are mixed, the mixing ratio of both is not especially limited in the present invention.

Here, in the case where the first solution contains nitric acid, the nitric acid concentration is desirably 1 to 60% by mass. In the case where the first solution contains hydrogen peroxide, the hydrogen peroxide concentration is desirably 1 to 35% by mass. It is more desirable that the nitric acid concentration be 2 to 30% by mass and the hydrogen peroxide concentration be 2 to 30% by mass.

The reason will be described below.

### Nitric Acid Concentration: 1 to 60% by Mass

The use of nitric acid oxidizes platinum and platinum alloys (for example, NiPt) as silicidation residual metals and the like. However, a nitric acid concentration of lower than 1% by mass does not give its sufficient action, whereas a nitric acid concentration exceeding 60% by mass gives too high an etching rate to metals (for example, Al) exposed on a substrate surface, silicides, Si-based insulation films, Si-based substrates and the like, which is not preferable.

Hence, the nitric acid concentration in the case containing nitric acid is desirably 1 to 60% by mass. Also for the same reason, it is more desirable that the lower limit be 2% by mass and the upper limit be 30% by mass.

### Hydrogen Peroxide Concentration: 1 to 35% by Mass

The use of hydrogen peroxide oxidizes platinum and platinum alloys (for example, NiPt) as silicidation residual metals and the like. However, a hydrogen peroxide concentration of lower than 1% by mass does not give its sufficient action, whereas a hydrogen peroxide concentration exceeding 35% by mass gives too high an etching rate to metals (for example, Al) exposed on a substrate surface, silicides, Si-based insulation films, Si-based substrates and the like, which is not preferable.

Hence, the hydrogen peroxide concentration in the case containing hydrogen peroxide is desirably 1 to 35% by mass. Also for the same reason, it is desirable that the lower limit be 2% by mass, and it is more desirable that the lower limit be 5% by mass and the upper limit be 32% by mass. Also for the same reason, it is still more desirable that the lower limit be 10% by mass, and the upper limit be 30% by mass.

The first solution contains nitric acid and/or hydrogen peroxide as main solutes; and either one thereof or both thereof are desirably contained in 80% or more in mass ratio with respect to the whole solutes, and more desirably contained in 90% or more. Nitric acid and/or hydrogen peroxide are desirably contained in 1% by mass or more in the sum total of concentrations thereof. Further in the case where the first solution contains other solutes other than the above solutes, the first solution can contain sulfuric acid, phosphoric acid, hydrochloric acid, hydrofluoric acid and the like; and the total of their concentrations is lower than 20% with respect to the whole solutes, preferably lower than 10%.

A suitable example of a solvent of the first solution is water.

Further the temperature of the first solution in the first cleaning step is desirably 25 to 100° C. Lower than 25° C. gives an insufficient cleaning ability. By contrast, 40° C. or higher gives an almost sufficient cleaning ability, and 40° C. or higher is more desirable. When the solution temperature exceeds 100° C., etching of Al and the like is promoted. Therefore, it is desirable that the upper limit be 100° C., and it is more desirable from the point of the energy efficiency and the etching rate that the temperature be 80° C. or lower.

Here, in the case of regulating the solution temperature, the solution is made to have the above temperature when the mixed solution is brought into contact with a semiconductor substrate.

In the first cleaning step using the first solution, the cleaning is carried out by bringing the first solution into contact with a semiconductor substrate, and the contact can be made by immersion of the semiconductor substrate in the first solution, or spraying, dropping, pouring or the like thereof on the semiconductor substrate. The contact time in the contact is not especially limited in the present invention, but can be, for example, 10 to 300 sec. The contact time of shorter than 10 sec brings about insufficient oxidation of platinum and platinum alloys (for example, NiPt) as silicidation residual metals; and the contact time exceeding 300 sec gives too high an etching rate to metals (for example, Al) exposed on a substrate surface, silicides, Si-based insulating films, Si-based substrates and the like, which are not preferable. Here, for the same reason, it is desirable that the lower limit of the contact time be 20 sec, and the upper limit of the contact time be 200 sec.

The second solution contains persulfuric acid and a halide; and the sum total of the concentration of the halide is desirably 0.001 to 2 mol/L. The halide can be one or more selected from the group consisting of chlorides, bromides and iodides.

A solvent of the second solution suitably includes water. Hereinafter, the reason of the sum total of the concentration of the halide will be described.

Halide Concentration: 0.001 mol/L to 2 mol/L

The use of the halide provides the action of dissolving Pt. However, when the sum total of the concentration of the halide is lower than 0.001 mol/L, the removal rate of platinum and platinum alloys (for example, NiPt) as silicidation residual metals is low; and when the sum total of the concentration of the halide exceeds 0.2 mol/L, damage is liable to be imparted to silicides, Si-based insulating films, Si-based substrates and the like. Hence, the sum total of the concentration of the halide in the second solution is desirably 0.001 mol/L to 2 mol/L. Also for the same reason, the lower limit of the sum total of the concentration of the halide is desirably 0.005 mol/L; and the upper limit thereof is desirably 1 mol/L.

Examples of a sulfuric acid solution having an oxidizing agent in the second solution include ones containing persulfuric acid as an oxidizing agent, and the sulfuric acid solution having an oxidizing agent can be one or more selected from sulfuric acid electrolytic solutions, mixed solutions of sulfuric acid and hydrogen peroxide and mixed solutions of sulfuric acid and ozone. Here, examples of persulfuric acid mentioned here include peroxodisulfuric acid and peroxomonosulfuric acid; and the persulfuric acid can be either one thereof or a mixture thereof. As oxidizing agents in the solution at this time, the persulfuric acid and hydrogen peroxide generated along with the autolysis of the persulfuric acid account for nearly the entire amount. Other oxidizing agents include ozone and hydrogen peroxide.

Oxidizing Agent Concentration: 0.001 to 2 mol/L

The use of an oxidizing agent such as persulfuric acid provides the action of dissolving platinum and platinum alloys (for example, NiPt) as silicidation residual metals. However, when the sum total of the concentration of the whole oxidizing agent is lower than 0.001 mol/L, the cleaning power becomes insufficient; by contrast, when exceeding 2 mol/L, the etching rate of Al and the like becomes high, and damage becomes liable to be caused to silicides, Si-based insulating films, Si-based substrates and the like. Hence, the oxidizing agent concentration in the second solution is desirably 0.001 to 2 mol/L. Also for the same reason, the lower limit of the oxidizing agent concentration in the second solution is more desirably 0.005 mol/L; and the upper limit of the oxidizing agent concentration in the second solution is more desirably 0.5 mol/L.

### Sulfuric Acid Concentration: 40 to 80% by Mass

The use of sulfuric acid provides the action of dissolving platinum and platinum alloys (for example, NiPt) as silicidation residual metals. However, when the sulfuric acid concentration in the second solution is lower than 40% by mass, the cleaning power becomes insufficient; by contrast, when the sulfuric acid concentration exceeds 80% by mass, the etching rate of Al and the like becomes high. Hence, the sulfuric acid concentration in the second solution is desirably 40 to 80% by mass. Also for the same reason, the lower limit of the sulfuric acid concentration in the second solution is more desirably 50% by mass; and the upper limit of the sulfuric acid concentration in the second solution is more desirably 75% by mass.

The second solution can contain other solutes other than the sulfuric acid-based oxidizing agent and the halide.

In the second cleaning step, the temperature of the second solution is desirably 25 to 100° C. Lower than 25° C. gives an insufficient cleaning ability. Here, if the temperature is 40° C. or higher, the cleaning ability is almost sufficient, and 40° C. or higher is more desirable. When the solution temperature exceeds 100° C., since silicides, Si-based insulating films, Si-based substrates and the like are damaged, it is desirable that the upper limit be 100° C.; however, it is more desirable from the point of the energy efficiency and the etching rate that the temperature be 80° C. or lower.

Here, in the case of regulating the solution temperature, the solution is made to have the above temperature when the mixed solution is brought into contact with a semiconductor substrate.

In the second cleaning step using the second solution, the cleaning is carried out by bringing the second solution into contact with a semiconductor substrate, but the contact can be made by immersion of the semiconductor substrate in the second solution, or spraying, dropping, pouring or the like thereof on the semiconductor substrate. The contact time in the contact is not especially limited in the present invention, but can be, for example, 10 to 300 sec. Shorter than 10 sec brings about insufficient cleaning; and the contact time exceeding 300 sec damages silicides, Si-based insulating films, Si-based substrates and the like. Also for the same reason, it is desirable that the lower limit of the contact time be 15 sec, and the upper limit of the contact time be 200 sec.

Contact methods of the solutions can be different between in the first cleaning step and the second cleaning step.

Between the first cleaning step and the second cleaning step, there may further be provided a first solution discharge step of discharging the first solution from a semiconductor substrate cleaned in the first cleaning step. In the first solution discharge step, cleaning using a rinsing liquid, for example, ultrapure water can be carry out.

The cleaning may be of a batch type or a single-substrate type, but the single-substrate type is better in the point of the contact efficiency.

A semiconductor substrate being a cleaning object in the present invention is one having a layer having Si as a constituting element; and a silicidation-treated semiconductor substrate, or Si-based substrate coated with an insulating film constituted of a Si compound or with a Si-based semiconductor film can be the object. As the semiconductor substrate having undergone a silicidation treatment, particularly a semiconductor substrate on which Al is partially exposed is more suitably. Examples of the insulating film constituted of a Si compound include SiO₂ and SiN. Examples of the Si-based semiconductor constituting the Si-based substrate include a Si single-element semiconductor and Si compound semiconductors such as SiC, SiGe and SiGePt (germanide). However, the semiconductor substrate having a layer having Si as a constituting element is not limited thereto.

### Advantageous Effects of Invention

The present invention can carry out cleaning to effectively and completely remove platinum and platinum alloys (for example, NiPt) as silicidation residual metals while suppressing damage to silicides, Si-based insulating films, Si-based substrates and the like. Particularly in the case where Al is exposed on a wafer surface, the present invention can carry out the cleaning while suppressing damage to Al in a predetermined level or less.

### BRIEF DESCRIPTION OF DRAWING

FIG. 1 is a diagram illustrating a semiconductor substrate cleaning system according to one embodiment of the present invention.

### MODE FOR CARRYING OUT THE INVENTION

### Embodiment 1

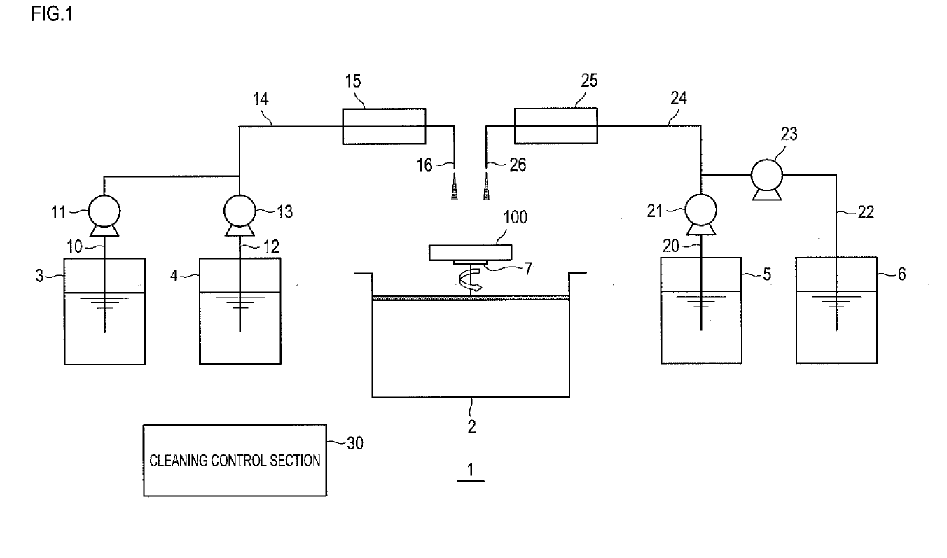

Hereinafter, a semiconductor substrate cleaning system 1 according to one embodiment of the present invention will be described based on FIG. 1.

The semiconductor substrate cleaning system 1 comprises a single-substrate cleaning machine 2 corresponding to a cleaning section according to the present invention, a nitric acid solution storage tank 3 to store a nitric acid solution, a hydrogen peroxide solution storage tank 4 to store a hydrogen peroxide solution, a sulfuric acid solution storage tank 5 to store a sulfuric acid solution containing persulfuric acid, and a halide solution storage tank 6 to store a halide solution containing one or more of halides, bromides and iodides.

Here, the nitric acid solution and the hydrogen peroxide solution correspond to a first solution in the present embodiment; and the nitric acid solution storage tank 3 and the hydrogen peroxide solution storage tank 4 correspond to a first solution-accommodating section in the present embodiment.

Further the sulfuric acid solution and the halide solution correspond to a second solution in the present embodiment; and the sulfuric acid solution storage tank 5 and the halide solution storage tank 6 correspond to a second solution-accommodating section in the present embodiment.

To the nitric acid solution storage tank 3, a nitric acid solution supply line 10 is connected through a liquid feed pump 11; and to the hydrogen peroxide solution storage tank 4, a hydrogen peroxide solution supply line 12 is connected through a liquid feed pump 13. The nitric acid solution supply line 10 and the hydrogen peroxide solution supply line 12 merge on the downstream sides thereof and constitute a first solution common liquid feed line 14; and on the downstream end side of the first solution common liquid feed line 14, a delivery nozzle 16 is connected through a heater 15. The heater 15 passes through and heats the solution in a once-through manner, and a near-infrared heater or the like can suitably be used.

The nitric acid solution supply line 10, the hydrogen peroxide solution supply line 12 and the first solution common liquid feed line 14 constitute a first solution supply line in the present embodiment. The heater 15 corresponds to a first solution temperature-regulating section in the present embodiment, and the delivery nozzle 16 corresponds to a first solution delivery section in the present embodiment.

Further to the sulfuric acid solution storage tank 5, a sulfuric acid solution supply line 20 is connected through a liquid feed pump 21; and to the halide solution storage tank 6, a halide solution supply line 22 is connected through a liquid feed pump 23. The sulfuric acid solution supply line and the halide solution supply line 22 merge on the downstream sides thereof and constitute a second solution common liquid feed line 24; and on the downstream end side of the second solution common liquid feed line 24, a delivery nozzle 26 is connected through a heater 25. The heater 25 passes through and heats the solution in a once-through manner, and a near-infrared heater or the like can suitably be used.

The sulfuric acid solution supply line 20, the halide solution supply line 22 and the second solution common liquid feed line 24 constitute a second solution supply line in the present embodiment; and the heater 25 corresponds to a second solution temperature-regulating section in the present embodiment, and the delivery nozzle 26 corresponds to a second solution delivery section in the present embodiment.

The single-substrate type cleaning machine 2 has a semiconductor substrate support table 7; and the semiconductor substrate support table 7 can be rotationally driven by a drive unit not shown in Figure. The single-substrate type cleaning machine 2 corresponds to a cleaning section in the present embodiment; and to a semiconductor substrate 100 supported on the semiconductor substrate support table 7, the solutions for cleaning are delivered from the delivery nozzles 16 and 26. The delivery nozzles 16 and 26 are constituted so that the solutions for cleaning are sprayed, dropped or poured on the semiconductor substrate 100. Here, the dropping and the pouring may be spraying the solutions to the semiconductor substrate 100 by imparting a pressure.

The semiconductor substrate cleaning system 1 further has a cleaning control section 30 to control the whole of the semiconductor substrate cleaning system 1. The cleaning control section 30 is constituted of a CPU, a memory section to store programs to operate it and operation parameters, and to be used as a work area, and the like.

The cleaning control section 30 controls operations of the liquid feed pumps 11, 13, 21 and 23, the heaters 15 and 25, and the single-substrate type cleaning machine 2. These apparatuses may be ones in which the setting, regulation and on-off of their operations are manually operated.

Then, a semiconductor substrate cleaning method using the semiconductor substrate cleaning system will be described hereinafter.

First, a silicidation-treated semiconductor substrate having Al partially exposed thereon, a semiconductor substrate having a Si-based insulating film, a Si-based substrate or the like is supported on the substrate support table. As the silicidation-treated semiconductor substrate, there can be used, for example, one in which a metal film is formed on a silicon substrate having Al present thereon, and the silicon substrate is subjected to an annealing treatment to thereby form a silicide layer containing a noble metal such as platinum on the silicon substrate. The metal film may contain a noble metal such as platinum.

However, the method for manufacturing a semiconductor substrate according to the present invention is not limited thereto.

Here, a suitable object example according to the present embodiment is the case where the film thickness of Al is 60 nm or thinner (preferably 30 nm or thinner); the thickness of the silicide layer is 60 nm or thinner (preferably 25 nm or thinner); and the gate width is 45 nm or smaller (preferably nm or smaller). However, the semiconductor substrate being an object in the present invention is not limited to the case.

Further the nitric acid solution storage tank 3 accommodates a nitric acid solution whose nitric acid concentration has been regulated so as to become 1 to 60% by mass when the nitric acid solution is mixed with hydrogen peroxide described below. Further in the hydrogen peroxide solution storage tank 4, the hydrogen peroxide concentration is regulated so as to become 1 to 35% by mass when the hydrogen peroxide is mixed with nitric acid described above.

The sulfuric acid solution storage tank 5 accommodates a sulfuric acid solution containing persulfuric acid whose sulfuric acid concentration has been regulated so as to become 40 to 80% by mass when the sulfuric acid solution is mixed with a solution containing a halide such as a chloride, a bromide and an iodide described below. Further the halide solution storage tank 6 accommodates a halide solution whose halide concentration sum total is regulated so as to become 0.001 to 2 mol/L when the halide solution is mixed with the sulfuric acid solution described above.

In cleaning the semiconductor substrate 100, while the semiconductor substrate 100 is rotationally supported on the semiconductor support table 7 by rotationally driving the semiconductor support table 7, first, the nitric acid solution in the nitric acid solution storage tank 3 is fed in a predetermined flow amount through the nitric acid solution supply line 10 by the liquid feed pump 11; further the hydrogen peroxide solution in the hydrogen peroxide solution storage tank 4 is fed in a predetermined flow amount through the hydrogen peroxide solution supply line 12 by the liquid feed pump 13; and these two solutions are fed through the first solution common liquid feed line 14 while being mixed therein to thereby prepare a first solution, and heated by the heater 15 in the once-through manner. The heating temperature is regulated so that when the first solution after being heated is brought into contact with the semiconductor substrate 100, the solution temperature becomes 25 to 100° C.

The mixing ratio of the nitric acid solution and the hydrogen peroxide can be set by regulating the liquid feed amounts by the liquid feed pump 11 and the liquid feed pump 13; the temperature of the first solution can be regulated by the heating temperature of the heater 15, and the like; and the above regulation can be carried out by the control by the cleaning control section 30 or by the manual operation.

The first solution prepared by mixing of the nitric acid solution and the hydrogen peroxide is delivered from the delivery nozzle 16 in the state of a nitric acid concentration of 1 to 30% by mass, a hydrogen peroxide concentration of 1 to 35% by mass, a sum total concentration of both of 1% by mass or higher, and a solution temperature of 35 to 100° C., and is brought into contact with the semiconductor substrate 100 to thereby carry out cleaning of the semiconductor substrate 100. Suitably, the nitric acid concentration is 2 to 30% by mass, and the hydrogen peroxide concentration is 2 to 30% by mass.

Here, it is desirable that the solution feed rate and the length of the first solution common liquid feed line 14 be determined so that the nitric acid solution and the hydrogen peroxide solution in the mixed state are brought into contact with the semiconductor substrate within 10 min (preferably 5 min) of a time point when the solution temperature in the mixed state is 25° C. or higher.

Further the time during which the mixed solution is brought into contact with the semiconductor substrate 100 is not limited to a specific range in the present invention, but is desirably in the range of 10 to 300 sec in the present embodiment.

The above treatment corresponds to a first cleaning step in the present embodiment.

Here, although the first solution-accommodating section is divided into the nitric acid solution storage tank 3 and the hydrogen peroxide solution storage tank 4 in the present embodiment, these may be accommodated as the first solution in one tank.

Then, the sulfuric acid solution in the sulfuric acid solution storage tank 5 is fed in a predetermined flow amount through the sulfuric acid solution supply line 20 by the liquid feed pump 21; further the solution containing one of a chloride, a ‘bromide and an iodide stored in the halide solution storage tank 6 is fed in a predetermined flow amount through the halide solution supply line 22 by the liquid feed pump 23; and these two solutions are fed through the second solution common liquid feed line 24 while being mixed therein to thereby prepare a second solution, and heated by the heater 25 in the once-through manner. The heating temperature is regulated so that when the second solution after being heated is brought into contact with the semiconductor substrate 100, the solution temperature becomes 25 to 100° C.

The mixing ratio of the sulfuric acid solution and the halide solution can be set by regulating the liquid feed amounts by the liquid feed pump 21 and the liquid feed pump 23; the temperature of the second solution can be regulated by the heating temperature of the heater 25, and the like; and the above regulation can be carried out by the control by the cleaning control section 30 or by the manual operation.

The second solution prepared by mixing of the sulfuric acid solution and the solution containing one of a chloride, a bromide and an iodide is delivered from the delivery nozzle 26 in the state of a sulfuric acid concentration of 40 to 80% by mass, an oxidizing agent concentration of 0.01 to 2 mol/L, and a solution temperature of 25 to 100° C., and is brought into contact with the semiconductor substrate 100 to thereby carry out cleaning of the semiconductor substrate 100. Here, it is desirable that the solution feed rate and the length of the second solution common liquid feed line 24 be determined so that the sulfuric acid solution and the solution containing one of a chloride, a bromide and an iodide in the mixed state are brought into contact with the semiconductor substrate 100 within 10 min (preferably 5 min) of a time point when the solution temperature in the mixed state is 25° C. or higher.

At this time, it is desirable that the cleaning be carried out under the above conditional range so that the etching rate of Al becomes 180 Å/min or lower, preferably 150 Å/min or lower; and that the cleaning be carried out under a condition of the cleaning time within about 120 sec, preferably within 80 sec.

The above treatment corresponds to a second cleaning step in the present embodiment.

The detail of the action of the above cleaning will be described hereinafter.

### <Al Etching Suppression>

It is assumed that by using the first solution, a film is formed on the surface of Al, and there can thereby be suppressed the etching when the cleaning is carried out using the first solution and the second solution.

### <Pt, Pt Alloy Exfoliation>

It is assumed as follows: by using the first solution according to the present invention, for example, in NiPt, Ni is dissolved; Pt also is oxidized to become liable to be etched; and then, by using the second solution, Pt reacts with a halogen-based oxidizing agent and is dissolved. Here, for either of Pt and a Pt alloy, it is assumed that if a Pt element is exposed on a substrate surface, the cleaning can be carried out by the same mechanism.

### <Suppression of Damage to the Silicide, the Si-Based Insulating Film, the Si-Based Substrate and the Like>

Although there is an aqua regia as a solution capable of exfoliating platinum and platinum alloys (for example, NiPt) while suppressing the etching of Al, the aqua regia damages the silicide, the Si-based insulating film and the Si-based substrate, since the aqua regia has a high concentration of Cl, which is supposed to be the cause of damaging the silicide, the Si-based insulating film and the Si-based substrate. The second solution according to the present embodiment, however, can suppress damage to the silicide, the Si-based insulating film and the Si-based substrate, since the second solution can have a reduced Cl concentration and take a shorter contact time of the solution with a wafer.

In the present embodiment, for example, when Pt on a Si substrate is removed, Pt can effectively be removed without damaging SiO₂; and when NiPt on a Si substrate is removed, NiPt can effectively be removed without damaging SiNiPt and Al. Further when Pt on a SiC substrate is removed, Pt can effectively be removed without damaging SiC; and when Pt on a SiGe substrate is removed, Pt can effectively be removed without damaging SiGe.

### <Reduction of the Treatment Time>

Although the present embodiment contains the two-stage treatment, it takes only a short treatment time and thus can shorten the time compared to conventional methods.

In the above present embodiment, the first cleaning step and the second cleaning step have been described, but a rinsing step using ultrapure water or the like can be carried out between these two steps. Carrying out the rinsing step securely removes the first solution and securely provides the cleaning effect by the second solution.

### EXAMPLES

Hereinafter, Examples according to the present invention and Comparative Examples will be shown. Here, in the Example and the Comparative Examples, the semiconductor substrate cleaning system illustrated in FIG. 1 was used.

### Example

A mixed solution composed of a solution containing nitric acid or hydrogen peroxide or both, as a first solution, was brought into contact with the semiconductor; and thereafter, a mixed solution composed of a sulfuric acid solution having persulfuric acid and a solution containing one halide of a chloride, a bromide and an iodide or a plurality thereof, as a second solution, was brought into contact with the semiconductor substrate.

In each of the cleaning, the mixed solution was heated and mixed, and thereafter immediately (within 10 min) the mixed solution was supplied for cleaning in which the mixed solution was brought into contact with a solid wafer described in the below.

In the below, as the most suitable evaluation, the case where the NiPt removal rate was 95% or higher was evaluated as good; and the case where lower than 95% was evaluated as poor. As the most suitable evaluation, the case where an Al etching rate exceeded 180 Å/min was evaluated as poor which means damaging Al; and the case of 180 Å/min or lower was evaluated as good.

Further with respect to the presence/absence of the silicide damage, the case of a surface roughness Ra of smaller than 1.7 μm was evaluated as absence of damage; and the case of a Ra of 1.7 μm or larger was evaluated as presence of damage. The test contents and the evaluation results are shown in Tables 1 and 2.

### Comparative Example 1

Cleaning was carried out at 50° C. for 50 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 without first solution but with a mixed solution as the second solution of an electrolytic sulfuric acid (sulfuric acid concentration: 65% by weight, oxidizing agent concentration: 0.04 mol/L) and 0.1 mol/L of hydrochloric acid, by bringing the solution into contact with the solid wafers at a rate of 200 ml/min. The solution after the treatment was subjected to a component analysis using an ICP-MS (inductively coupled plasma mass spectrometer, hereinafter, simply abbreviated to ICP-MS); the removal rate of NiPt from the wafer and the etching rate of Al were checked from the concentrations of Ni, Pt and Al in the solution; and the presence/absence of the silicide damage was checked by the observation of the wafer surface by an AFM (atomic force microscope, hereinafter, simply abbreviated to AFM). The results are shown in Table 1.

As the results, the NiPt removal rate was 20%; the Al etching rate was 80 Å/min; and there was no NiPt silicide damage.

### Comparative Example 2

Cleaning was carried out at 50° C. for 50 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 without first solution but with an aqua regia (hydrochloric acid concentration: 3 mol/L) as the second solution, by bringing the solution into contact with the solid wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 60%; the Al etching rate was 450 Å/min; and there was some NiPt silicide damage.

### Comparative Example 3

Cleaning was carried out at 50° C. for 50 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 without first solution but with a mixed solution as the second solution of an SPM solution (H₂SO₄:H₂O₂=2:1) having an oxidizing agent concentration of 2.14 mol/L and a sulfuric acid concentration of 65% by weight, and 0.1 mol/L of hydrochloric acid, by bringing the solution into contact with the solid wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the Al etching rate was 250 Å/min; there was some NiPt silicide damage; and the NiPt removal rate was 100%

### Comparative Example 4

Cleaning was carried out at 50° C. for 50 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 without first solution but with a mixed solution as the second solution of an SPM solution (H₂SO₄:H₂O₂=4:1) having an oxidizing agent concentration of 0.9 mol/L and a sulfuric acid concentration of 80%, and 0.1 mol/L of hydrochloric acid, by bringing the solution into contact with the solid wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the Al etching rate was 140 Å/min; there was no NiPt silicide damage; and the NiPt removal rate was 50%, which was insufficient.

### Reference Example 5

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution. Then, cleaning was carried out at 50° C. for 50 sec on the above-mentioned (1) NiPt wafer, and the above-mentioned (2) Al wafer, respectively, with an electrolytic sulfuric acid (sulfuric acid concentration: 30%, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 70%; the Al etching rate was 60 Å/min; and there was no NiPt silicide damage.

### Reference Example 6

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 90% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 50%; the Al etching rate was 250 Å/min; and there was no NiPt silicide damage.

### Comparative Example 7

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 20° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 10%; the Al etching rate was 50 Å/min; and there was no NiPt silicide damage.

### Comparative Example 8

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 120° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 1000 Å/min; and there was some NiPt silicide damage.

### Reference Example 9

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 0.1% by weight, hydrogen peroxide concentration: 0% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 40%; the Al etching rate was 120 Å/min; and there was no NiPt silicide damage.

### Reference Example 10

Cleaning was carried out at 50° C. for 30 sec on (1) a solid wafer having, a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 0% by weight, hydrogen peroxide concentration: 1% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 50%; the Al etching rate was 110 Å/min; and there was no NiPt silicide damage.

### Example 1

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 90 Å/min; and there was no NiPt silicide damage.

### Example 2

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, NaCl concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 90 Å/min; and there was no NiPt silicide damage.

### Example 3

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, HBr concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 90 Å/min; and there was no NiPt silicide damage.

### Example 4

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, HI concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 90 Å/min; and there was no NiPt silicide damage.

### Example 5

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 40% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 80 Å/min; and there was no NiPt silicide damage.

### Example 6

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 2.00 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 80% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 160 Å/min; and there was no NiPt silicide damage.

### Example 7

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 0% by weight, hydrogen peroxide concentration: 15% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 97%; the Al etching rate was 80 Å/min; and there was no NiPt silicide damage.

### Example 8

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 15% by weight, hydrogen peroxide concentration: 0% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 120 Å/min; and there was no NiPt silicide damage.

### Example 9

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 7% by weight, hydrogen peroxide concentration: 6% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 96%; the Al etching rate was 100 Å/min; and there was no NiPt silicide damage.

### Example 10

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 30% by weight, hydrogen peroxide concentration: 15% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 140 Å/min; and there was no NiPt silicide damage.

### Example 11

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 35° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the TCP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 70 Å/min; and there was no NiPt silicide damage.

### Example 12

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 90° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 160 Å/min; and there was no NiPt silicide damage.

### Example 13

Cleaning was carried out at 20° C. for 30 sec on (1) a solid wafer having a NiPt layer of 10 nm, stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 80%; the Al etching rate was 60 Å/min; and there was no NiPt silicide damage.

### Example 14

Cleaning was carried out at 30° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 80 Å/min; and there was no NiPt silicide damage.

### Example 15

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 90 Å/min; and there was no NiPt silicide damage.

### Example 16

Cleaning was carried out at 90° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 170 Å/min; and there was no NiPt silicide damage.

### Example 17

Cleaning was carried out at 100° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 180 Å/min; and there was no NiPt silicide damage.

### Example 18

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 1.8 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 120 Å/min; and there was no NiPt silicide damage.

### Example 19

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.002 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 80 Å/min; and there was no NiPt silicide damage.

### Example 20

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on, the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.002 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 80 Å/min; and there was no NiPt silicide damage.

### Example 21

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 1.5 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 150 Å/min; and there was no NiPt silicide damage.

### Example 22

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with a mixed solution (sulfuric acid concentration: 80% by weight, oxidizing agent concentration: 0.9 mol/L, hydrochloric acid concentration: 0.1 mol/L) as the second solution of an SPM solution (H₂SO₄:H₂O₂=4:1) and hydrochloric acid, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 140 Å/min; and there was no NiPt silicide damage.

### Example 23

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with a mixed solution (sulfuric acid concentration: 65% by weight, oxidizing agent concentration: 0.002 mol/L, hydrochloric acid concentration: 0.1 mol/L) as the second solution prepared by blowing ozone gas into a sulfuric acid solution and adding hydrochloric acid to the resultant solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 80 Å/min; and there was no NiPt silicide damage.

### Example 24

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (no nitric acid, hydrogen peroxide concentration: 30% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 80 Å/min; and there was no NiPt silicide damage.

### Example 25

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 40% by weight, no hydrogen peroxide), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 160 Å/min; and there was no NiPt silicide damage.

### Example 26

Cleaning was carried out at 50° C. for 7 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 80%; the Al etching rate was 85 Å/min; and there was no NiPt silicide damage.

### Example 27

Cleaning was carried out at 50° C. for 10 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 95%; the Al etching rate was 90 Å/min; and there was no NiPt silicide damage.

### Example 28

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with using the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 90 Å/min; and there was no NiPt silicide damage.

### Example 29

Cleaning was carried out at 50° C. for 80 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 170 Å/min; and there was no NiPt silicide damage.

### Example 30

Cleaning was carried out at 50° C. for 100 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2% by weight, hydrogen peroxide concentration: 29% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 180 Å/min; and there was no NiPt silicide damage.

Then, the same evaluation was made by adding other solutes other than nitric acid and hydrogen peroxide to the first solution. The test conditions and the evaluation results are shown in Table 2. Here, by reference, the contents of Example 1 are together shown in Table 2.

### Comparative Example 11

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2.0% by weight, hydrogen peroxide concentration: 29% by weight, sulfuric acid concentration: 30% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 190 Å/min; and there was some NiPt silicide damage.

### Example 31

Cleaning was carried out at 50° C. for 30 sec on (1) a solid wafer having a NiPt layer of 10 nm stacked on a silicon wafer, and (2) a solid wafer having an Al layer of 500 nm stacked on a silicon wafer, respectively, by the single-substrate type cleaning machine in FIG. 1 with the first solution (nitric acid concentration: 2.0% by weight, hydrogen peroxide concentration: 29% by weight, sulfuric acid concentration: 15% by weight), by bringing the solution into contact with the solid wafers at a rate of 200 ml/min. Then, the wafers were rinsed with pure water to thereby remove the first solution; then, cleaning was carried out at 50° C. for 50 sec on the above-mentioned (1) NiPt wafer, and the above-mentioned (2) Al wafer, respectively, with an electrolytic sulfuric acid (sulfuric acid concentration: 65% by weight, oxidizing agent concentration: 0.04 mol/L, hydrochloric acid concentration: 0.1 mol/L) as the second solution, by bringing the solution into contact with the wafers at a rate of 0.200 ml/min. The solution after the treatment was subjected to a component analysis using the ICP-MS; the removal rate of NiPt from the wafer and the etching rate of Al were checked from the concentrations of Ni, Pt and Al in the solution; and the presence/absence of the silicide damage was checked by the observation of the wafer surface by the AFM. The results are shown in Table 1.

As the results, the NiPt removal rate was 100%; the Al etching rate was 160 Å/min; and there was no NiPt silicide damage.

TABLE 1

| | | First Solution | | | | Second Solution | | |
|---|---|---|---|---|---|---|---|---|
| | | Concentration | Concentration of | Processing | | | Concentration of | Halogen |
| Sample | | of Nitric | Hydrogen | Time | Temperature | | Oxidizing Agent | concentration |
| No. | | Acid [wt %] | Peroxide [wt %] | [sec] | [° C.] | Kind of Solution | [mol/L] | [mol/L] |
| Comparative | 1 | — | — | — | — | Electrolysis Sulfuric Acid + HCl | 0.04 | 0.10 |
| Examples | 2 | — | — | — | — | Aqua Regia | — | 3 |
| | 3 | — | — | — | — | SPM 2:1 + HCl | 2.14 | 0.10 |
| | 4 | — | — | — | — | SPM4:1 + HCl | 0.9 | 0.10 |
| Reference | 5 | 2 | 29 | 30 | 50 | Electrolysis Sulfuric Acid + HCl | 0.04 | 0.10 |
| Examples | 6 | 2 | 29 | 30 | 50 | Electrolysis Sulfuric Acid + HCl | 0.04 | 0.10 |
| Comparative | 7 | 2 | 29 | 30 | 50 | Electrolysis Sulfuric Acid + HCl | 0.04 | 0.10 |
| Examples | 8 | 2 | 29 | 30 | 50 | Electrolysis Sulfuric Acid + HCl | 0.04 | 0.10 |
| Raference | 9 | 0.1 | 0 | 30 | 50 | Electrolysis Sulfuric Acid + HCl | 0.04 | 0.10 |
| Examples | 10 | 0 | 1 | 30 | 50 | Electrolysis Sulfuric Acid + HCl | 0.04 | 0.10 |
| Examples | 1 | 2 | 29 | 30 | 50 | Electrolysis Sulfuric Acid + HCl | 0.04 | 0.10 |
| | 2 | 2 | 29 | 30 | 50 | Electrolysis Sulfide Acid + NaCl | 0.04 | 0.10 |
| | 3 | 2 | 29 | 30 | 50 | Electrolysis Sulfuric Acid + HBr | 0.04 | 0.10 |
| | 4 | 2 | 29 | 30 | 50 | Electrolysis Sulfuric Acid + HI | 0.04 | 0.10 |
| | 5 | 2 | 29 | 30 | 50 | Electrolysis Sulfuric Acid + HCl | 0.04 | 0.10 |
| | 6 | 2 | 29 | 30 | 50 | Electrolysis Sulfuric Acid + HCl | 0.04 | 0.10 |
| | 7 | 0 | 15 | 30 | 50 | Electrolysis Sulfuric Acid + HCl | 0.04 | 0.10 |
| | 8 | 15 | 0 | 30 | 50 | Electrolysis Sulfuric Acid + HCl | 0.04 | 0.10 |
| | 9 | 7 | 6 | 30 | 50 | Electrolysis Sulfuric Acid + HCl | 0.04 | 0.10 |
| | 10 | 30 | 15 | 30 | 50 | Electrolysis Sulfuric Acid + HCl | 0.04 | 0.10 |
| | 11 | 2 | 29 | 30 | 50 | Electrolysis Sulfuric Acid + HCl | 0.04 | 0.10 |
| | 12 | 2 | 29 | 30 | 50 | Electrolysis Sulfuric Acid + HCl | 0.04 | 0.10 |
| | 13 | 2 | 29 | 30 | 20 | Electrolysis Sulfuric Acid + HCl | 0.04 | 0.10 |
| | 14 | 2 | 29 | 30 | 30 | Electrolysis Sulfuric Acid + HCl | 0.04 | 0.10 |
| | 15 | 2 | 29 | 30 | 50 | Electrolysis Sulfuric Acid + HCl | 0.04 | 0.10 |
| | 16 | 2 | 29 | 30 | 90 | Electrolysis Sulfuric Acid + HCl | 0.04 | 0.10 |
| | 17 | 2 | 29 | 30 | 100 | Electrolysis Sulfuric Acid + HCl | 0.04 | 0.10 |
| | 18 | 2 | 29 | 30 | 50 | Electrolysis Sulfuric Acid + HCl | 1.80 | 0.10 |
| | 19 | 2 | 29 | 30 | 50 | Electrolysis Sulfuric Acid + HCl | 0.002 | 0.10 |
| | 20 | 2 | 29 | 30 | 50 | Electrolysis Sulfuric Acid + HCl | 0.04 | 0.002 |
| | 21 | 2 | 29 | 30 | 50 | Electrolysis Sulfuric Acid + HCl | 0.04 | 1.50 |
| | 22 | 2 | 29 | 30 | 50 | SPM4:1 + HCl | 0.9 | 0.10 |
| | 23 | 2 | 29 | 30 | 50 | Sulfuric Acid + Ozone + HCl | 0.002 | 0.10 |
| | 24 | 0 | 30 | 30 | 50 | Electrolysis Sulfuric Acid + HCl | 0.04 | 0.10 |
| | 25 | 40 | 0 | 30 | 50 | Electrolysis Sulfuric Acid + HCl | 0.04 | 0.10 |
| | 26 | 2 | 29 | 7 | 50 | Electrolysis Sulfuric Acid + HCl | 0.04 | 0.10 |
| | 27 | 2 | 29 | 10 | 50 | Electrolysis Sulfuric Acid + HCl | 0.04 | 0.10 |
| | 28 | 2 | 29 | 30 | 50 | Electrolysis Sulfuric Acid + HCl | 0.04 | 0.10 |
| | 29 | 2 | 29 | 80 | 50 | Electrolysis Sulfuric Acid + HCl | 0.04 | 0.10 |
| | 30 | 2 | 29 | 100 | 50 | Electrolysis Sulfuric Acid + HCl | 0.04 | 0.10 |

| | | Second Solution | | | | | | |
|---|---|---|---|---|---|---|---|---|
| | | Sulfuric Acid | | Processing | Evaluation Result | | | |
| Sample | | Concentration | Temperature | Time | Removal Rate | Etching Rate | Silicide damage | |
| No. | | [wt %] | [° C.] | [sec] | Of NiPt [%] | of Al [Å] | of NiPt | Note |
| Comparative | 1 | 65 | 50 | 50 | 20 | 80 | No | Without |
| Examples | 2 | 0 | 50 | 50 | 60 | 450 | Yes | processing of |
| | 3 | 65 | 50 | 50 | 100 | 250 | Yes | nitric acid• |
| | 4 | 80 | 50 | 50 | 50 | 140 | No | hydrogen |
| | | | | | | | | peroxide |
| Reference | 5 | 30 | 50 | 50 | 70 | 60 | No | concentration is |
| Examples | 6 | 90 | 50 | 50 | 50 | 250 | No | out of range |
| Comparative | 7 | 65 | 20 | 50 | 10 | 50 | No | Temperature is |
| Examples | 8 | 65 | 120 | 50 | 100 | 1000 | Yes | out of range |
| Raference | 9 | 65 | 50 | 50 | 40 | 120 | No | Sum of nitric acid |
| Examples | 10 | 65 | 50 | 50 | 50 | 110 | No | concentration and |
| | | | | | | | | hydrogen peroxide |
| | | | | | | | | concentration |
| Examples | 1 | 65 | 50 | 50 | 100 | 90 | No | Examination of |
| | 2 | 65 | 50 | 50 | 100 | 90 | No | type of agent |
| | 3 | 65 | 50 | 50 | 100 | 90 | No | |
| | 4 | 65 | 50 | 50 | 100 | 90 | No | |
| | 5 | 40 | 50 | 50 | 95 | 80 | No | Examination of |
| | 6 | 80 | 50 | 50 | 100 | 160 | No | sulfuric acid |
| | | | | | | | | concentration |
| | 7 | 65 | 50 | 50 | 97 | 80 | No | Sum of nitric acid |
| | 8 | 65 | 50 | 50 | 95 | 120 | No | concentration and |
| | 9 | 65 | 50 | 50 | 96 | 100 | No | hydrogen peroxide |
| | 10 | 65 | 50 | 50 | 100 | 140 | No | concentration |
| | 11 | 65 | 35 | 50 | 95 | 70 | No | Examination of |
| | 12 | 65 | 90 | 50 | 100 | 160 | No | temperature |
| | 13 | 65 | 50 | 50 | 80 | 60 | No | Processing |
| | 14 | 65 | 50 | 50 | 95 | 80 | No | temperature |
| | 15 | 65 | 50 | 50 | 100 | 90 | No | |
| | 16 | 65 | 50 | 50 | 100 | 170 | No | |
| | 17 | 65 | 50 | 50 | 100 | 180 | No | |
| | 18 | 65 | 50 | 50 | 100 | 120 | No | Examination of |
| | 19 | 65 | 50 | 50 | 95 | 80 | No | oxidizing agent |
| | | | | | | | | concentration |
| | 20 | 65 | 50 | 50 | 95 | 80 | No | Examination of |
| | 21 | 65 | 50 | 50 | 100 | 150 | No | halogen |
| | | | | | | | | concentration |
| | 22 | 80 | 50 | 50 | 100 | 140 | No | Type of second |
| | 23 | 65 | 50 | 50 | 95 | 80 | No | solution |
| | 24 | 65 | 50 | 50 | 95 | 80 | No | Nitric acid or |
| | 25 | 65 | 50 | 50 | 95 | 160 | No | hydrogen peroxide |
| | | | | | | | | is out of range |
| | 26 | 65 | 50 | 50 | 80 | 85 | No | Processing time |
| | 27 | 65 | 50 | 50 | 95 | 90 | No | |
| | 28 | 65 | 50 | 50 | 100 | 90 | No | |
| | 29 | 65 | 50 | 50 | 100 | 170 | No | |
| | 30 | 65 | 50 | 50 | 100 | 180 | No | |

TABLE 2

| | First Solution | | | | | Second Solution | | |
|---|---|---|---|---|---|---|---|---|
| | Concentration | Concentration of | | Processing | | | Concentration of | Halogen |
| Sample | of Nitric | Hydrogen | Concentration of | Time | Temperature | Kind of | Oxidizing Agent | ConcentRation |
| No. | Acid [wt %] | Peroxide [wt %] | Other Acid [wt %] | [sec] | [° C.] | Solution | [mol/L] | [mol/L] |
| Comparative | 2.0 | 29 | Sulfuric | 30 | 50 | Electrolysis | 0.04 | 0.10 |
| Example 11 | | | Acid | | | Sulfuric | | |
| | | | (30) | | | Acid + HCl | | |
| Example 31 | 2.0 | 29 | Sulfuric | 30 | 50 | Electrolysis | 0.04 | 0.10 |
| | | | Acid | | | Sulfuric | | |
| | | | (15) | | | Acid + HCl | | |
| Example 1 | 2 | 29 | 0 | 30 | 50 | Electrolysis | 0.04 | 0.10 |
| | | | | | | Sulfuric | | |
| | | | | | | Acid + HCl | | |

| | Second Solution | | | | | | |
|---|---|---|---|---|---|---|---|
| | Sulfuric Acid | | Processing | Evaluation Result | | | |
| Sample | concentration | Temperature | Time | Removal Rate | Etching Rate | Silicide damage | |
| No. | [wt %] | [° C.] | [sec] | of NiPt [%] | of Al [Å] | of NiPt | Note |
| Comparative | 65 | 50 | 50 | 100 | 190 | Yes | Concentration of |
| Example 11 | | | | | | | Other Acid |
| Example 31 | 65 | 50 | 50 | 100 | 160 | No | |
| Example 1 | 65 | 50 | 50 | 100 | 90 | No | |

Then, the test examples are shown in each of the following Tables collectively for each test item.

With respect to the presence/absence of the first cleaning, part of the test examples in Table 1 are taken out therefrom and shown in the following Table 3.

By carrying out the first cleaning in which the test object is brought into contact with nitric acid and/or hydrogen peroxide, the effect was enhanced. Here, E/R of Al in the Table indicates an etching rate of Al (hereinafter, the same will be applied)

TABLE 3
Presence/absence of the first cleaning

| | First Solution | | | | Second Solution | |
|---|---|---|---|---|---|---|
| Sample | Concentration of | Concentration of | Processing Time | Temperature | | Oxidizing Agent |
| No. | Nitric Acid [wt %] | Hydrogen Peroxide [wt %] | [sec] | [° C.] | Kind of Solution | [mol/L] |
| Comparative | — | — | — | — | Electrolysis | 0.04 |
| Example 1 | | | | | Sulfuric | |
| | | | | | Acid + HCl | |
| Example 1 | 2 | 29 | 30 | 50 | Same as above | Same |
| | | | | | | as |
| | | | | | | above |
| Comparative | — | — | — | — | SPM4:1 + HCl | 0.9 |
| Example 4 | | | | | | |
| Example 22 | 2 | 29 | 30 | 50 | Same as above | Same |
| | | | | | | as |
| | | | | | | above |

| | Second Solution | | | | Evaluation Result | | |
|---|---|---|---|---|---|---|---|
| Sample | | Sulfuric Acid | | | Removal Rate | E/R | |
| No. | Halogen [mol/L] | concentration [wt %] | Temperature [° C.] | Time [sec] | of NiPt [%] | of Al [Å] | Damage |
| Comparative | 0.10 | 65 | 50 | 50 | 20 | 80 | No |
| Example 1 | | | | | | | |
| Example 1 | Same | Same | Same | Same | 100 | 90 | Same |
| | as | as | as | as | | | as |
| | above | above | above | above | | | above |
| Comparative | Same | 80 | Same | Same | 50 | 140 | Same |
| Example 4 | as | | as | as | | | as |
| | above | | above | above | | | above |
| Example 22 | Same | Same | Same | Same | 100 | Same | Same |
| | as | as | as | as | | as | as |
| | above | above | above | above | | above | above |

Then, part of the test examples in Table 1 are taken out therefrom, based on the difference in the concentration between the sulfuric acid and the hydrogen peroxide, and shown in the following Table 4. Further the following additional test was carried out and the results are shown in Table 4 similarly.

### Comparative Example 12

The test was carried out under the same condition as in Example 1, except for altering the first solution to a first solution (nitric acid concentration: 62% by weight, hydrogen peroxide concentration: 0% by weight).

As the results, the NiPt removal rate was 100%; the Al etching rate was 190 Å/min; and there was some NiPt silicide damage.

### Comparative Example 13

The test was carried out under the same condition as in Example 1, except for altering the first solution to a first solution (nitric acid concentration: 0% by weight, hydrogen peroxide concentration: 0.1% by weight).

As the results, the NiPt removal rate was 25%; the Al etching rate was 140 Å/min; and there was no NiPt silicide damage.

### Reference Example 1

The test was carried out under the same condition as in Example 1, except for altering the first solution to a first solution (nitric acid concentration: 0% by weight, hydrogen peroxide concentration: 1% by weight).

As the results, the NiPt removal rate was 40%; the Al etching rate was 120 Å/min; and there was no NiPt silicide damage.

### Reference Example 2

The test was carried out under the same condition as in Example 1, except for altering the first solution to a first solution (nitric acid concentration: 0.1% by weight, hydrogen peroxide concentration: 0% by weight).

As the results, the NiPt removal rate was 50%; the Al etching rate was 110 Å/min; and there was no NiPt silicide damage.

### Example 32

The test was carried out under the same condition as in Example 1, except for altering the first solution to a first solution (nitric acid concentration: 1% by weight, hydrogen peroxide concentration: 0% by weight).

As the results, the NiPt removal rate was 95%; the Al etching rate was 115 Å/min; and there was no NiPt silicide damage.

### Example 33

The test was carried out under the same condition as in Example 1, except for altering the first solution to a first solution (nitric acid concentration: 60% by weight, hydrogen peroxide concentration: 0% by weight).

As the results, the NiPt removal rate was 100%; the Al etching rate was 160 Å/min; and there was no NiPt silicide damage.

### Example 34

The test was carried out under the same condition as in Example 1, except for altering the first solution to a first solution (nitric acid concentration: 0% by weight, hydrogen peroxide concentration: 2% by weight).

As the results, the NiPt removal rate was 95%; the Al etching rate was 115 Å/min; and there was no NiPt silicide damage.

### Example 35

The test was carried out under the same condition as in Example 1, except for altering the first solution to a first solution (nitric acid concentration: 0% by weight, hydrogen peroxide concentration: 35% by weight).

As the results, the NiPt removal rate was 95%; the Al etching rate was 80 Å/min; and there was no NiPt silicide damage.

As seen in Table 4, the good cleaning effect was attained by setting the nitric acid concentration to 1 to 60% by mass and the hydrogen peroxide concentration to 2 to 35% by mass.

TABLE 4
Concentration of Nitric acid•Hydrogen peroxide

| | First Solution | | | | Second Solution | |
|---|---|---|---|---|---|---|
| Sample | Concentration of | Concentration of | | | | Oxidizing Agent |
| No. | Nitric Acid [wt %] | Hydrogen Peroxide [wt %] | Time [sec] | Temperature [° C.] | Kind of Solution | [mol/L] |
| Example 9 | 7 | 6 | 30 | 50 | Electrolysis Sulfuric | 0.04 |
| | | | | | Acid + HCl | |
| Example 1 | 2 | 29 | Same | Same | Same as above | Same |
| | | | As | as | | As |
| | | | above | above | | above |
| Example 10 | 30 | 15 | Same | Same | Same as above | Same |
| | | | as | as | | as |
| | | | above | above | | above |
| Reference | 0.1 | 0 | Same | Same | Same as above | Same |
| Example 2 | | | as | as | | as |
| | | | above | above | | above |
| Example 32 | 1 | 0 | Same | Same | Same as above | Same |
| | | | as | as | | as |
| | | | above | above | | above |
| Example 8 | 15 | 0 | Same | Same | Same as above | Same |
| | | | as | as | | as |
| | | | above | above | | above |
| Example 25 | 40 | 0 | Same | Same | Same as above | Same |
| | | | as | as | | as |
| | | | above | above | | above |
| Example 33 | 60 | 0 | Same | Same | Same as above | Same |
| | | | as | as | | as |
| | | | above | above | | above |
| Comparative | 62 | 0 | Same | Same | Same as above | Same |
| Example 12 | | | as | as | | as |
| | | | above | above | | above |
| Comparative | 0 | 0.1 | Same | Same | Same as above | Same |
| Example 13 | | | as | as | | as |
| | | | above | above | | above |
| Reference | 0 | 1 | Same | Same | Same as above | Same |
| Example 1 | | | as | as | | as |
| | | | above | above | | above |
| Example 34 | 0 | 2 | Same | Same | Same as above | Same |
| | | | as | as | | as |
| | | | above | above | | above |
| Example 7 | 0 | 15 | Same | Same | Same as above | Same |
| | | | as | as | | as |
| | | | above | above | | above |
| Example 24 | 0 | 30 | Same | Same | Same as above | Same |
| | | | as | as | | as |
| | | | above | above | | above |
| Example 35 | 0 | 35 | Same | Same | Same as above | Same |
| | | | as | as | | as |
| | | | above | above | | above |

| | Second Solution | | | | Evaluation Result | | |
|---|---|---|---|---|---|---|---|
| Sample | | Sulfuric Acid | | | Removal Rate | E/R | |
| No. | Halogen [mol/L] | concentration [wt %] | Temperature [° C.] | Time [sec] | of NiPt [%] | of Al [Å] | Damage |
| Example 9 | 0.10 | 65 | 50 | 50 | 96 | 100 | No |
| Example 1 | Same | Same | Same | Same | 100 | 90 | Same |
| | as | as | as | as | | | as |
| | above | above | above | above | | | above |
| Example 10 | Same | Same | Same | Same | 100 | 140 | Same |
| | as | as | as | as | | | as |
| | above | above | above | above | | | above |
| Reference | Same | Same | Same | Same | 50 | 110 | Same |
| Example 2 | as | as | as | as | | | as |
| | above | above | above | above | | | above |
| Example 32 | Same | Same | Same | Same | 95 | 115 | Same |
| | as | as | as | as | | | as |
| | above | above | above | above | | | above |
| Example 8 | Same | Same | Same | Same | 95 | 120 | Same |
| | as | as | as | as | | | as |
| | above | above | above | above | | | above |
| Example 25 | Same | Same | Same | Same | 95 | 160 | Same |
| | as | as | as | as | | | as |
| | above | above | above | above | | | above |
| Example 33 | Same | Same | Same | Same | 100 | 160 | Same |
| | as | as | as | as | | | as |
| | above | above | above | above | | | above |
| Comparative | Same | Same | Same | Same | 100 | 190 | Yes |
| Example 12 | as | as | as | as | | | |
| | above | above | above | above | | | |
| Comparative | Same | Same | Same | Same | 25 | 140 | No |
| Example 13 | as | as | as | as | | | |
| | above | above | above | above | | | |
| Reference | Same | Same | Same | Same | 40 | 120 | Same |
| Example 1 | as | as | as | as | | | as |
| | above | above | above | above | | | above |
| Example 34 | Same | Same | Same | Same | 95 | 115 | Same |
| | as | as | as | as | | | as |
| | above | above | above | above | | | above |
| Example 7 | Same | Same | Same | Same | 97 | 80 | Same |
| | as | as | as | as | | | as |
| | above | above | above | above | | | above |
| Example 24 | Same | Same | Same | Same | 95 | 80 | Same |
| | as | as | as | as | | | as |
| | above | above | above | above | | | above |
| Example 35 | Same | Same | Same | Same | 95 | 80 | Same |
| | as | as | as | as | | | as |
| | above | above | above | above | | | above |

Then, part of the test examples in Table 1 are taken out therefrom based on the difference between the treatment times in the first cleaning step, and shown in Table 5. It is clear that the cleaning effect was enhanced by setting the treatment time of the first cleaning step to 10 to 100 sec, and setting the treatment time to 30 sec or longer is more desirable.

TABLE 5
First cleaning time

| | First Solution | | | | | |
|---|---|---|---|---|---|---|
| | Concentration | Concentration | | | Second Solution | |
| | of Nitric | of Hydrogen | | | | Oxidizing |
| Sample | Acid | Peroxide | Time | Temperature | | Agent |
| No. | [wt %] | [wt %] | [sec] | [° C.] | Kind of Solution | [mol/L] |
| Example 26 | 2 | 29 | 7 | 50 | Electrolysis Sulfuric | 0.04 |
| | | | | | Acid + HCl | |
| Example 27 | Same as | Same as | 10 | Same | Same as above | Same as |
| | above | above | | as | | above |
| | | | | above | | |
| Example 1 | Same as | Same as | 30 | Same | Same as above | Same as |
| | above | above | | as | | above |
| | | | | above | | |
| Example 29 | Same as | Same as | 80 | Same | Same as above | Same as |
| | above | above | | as | | above |
| | | | | above | | |
| Example 30 | Same as | Same as | 100 | Same | Same as above | Same as |
| | above | above | | as | | above |
| | | | | above | | |

| | Second Solution | | | | Evaluation Result | | |
|---|---|---|---|---|---|---|---|
| | | Sulfuric Acid | | | Removal | E/R | |
| Sample | Halogen | concentration | Temperature | Time | Rate of | of Al | |
| No. | [mol/L] | [wt %] | [° C.] | [sec] | NiPt [%] | [Å] | Damage |
| Example 26 | 0.10 | 65 | 50 | 50 | 80 | 85 | No |
| Example 27 | Same as | Same as | Same as | Same as | 95 | 90 | Same as |
| | above | above | above | above | | | above |
| Example 1 | Same as | Same as | Same as | Same as | 100 | 90 | Same as |
| | above | above | above | above | | | above |
| Example 29 | Same as | Same as | Same as | Same as | 100 | 170 | Same as |
| | above | above | above | above | | | above |
| Example 30 | Same as | Same as | Same as | Same as | 100 | 180 | Same as |
| | above | above | above | above | | | above |

Then, part of the test examples in Table 1 were taken out therefrom based on the difference between the temperatures of the first solution in the first cleaning step, and shown in Table 6. Further the following additional test was carried out, and the results are shown in Table 6 similarly.

### Comparative Example 14

The test was carried out under the same condition as in Example 1, except for altering the temperature of the first solution to 20° C.

As the results, the NiPt removal rate was 85%; the Al etching rate was 60 Å/min; and there was no NiPt silicide damage.

### Comparative Example 15

The test was carried out under the same condition as in Example 1, except for altering the temperature of the first solution to 120° C.

As the results, the NiPt removal rate was 100%; the Al etching rate was 300 Å/min; and there was some NiPt silicide damage.

### Example 36

The test was carried out under the same condition as in Example 1, except for altering the temperature of the first solution to 25° C.

As the results, the NiPt removal rate was 95%; the Al etching rate was 70 Å/min; and there was no NiPt silicide damage.

From the results of Table 6, it is clear that by setting the temperature of the first solution to 25 to 100° C., the cleaning effect was enhanced, and setting the temperature to 50° C. or higher was more desirable.

TABLE 6
First cleaning temperature

| | First Solution | | | | Second Solution | | |
|---|---|---|---|---|---|---|---|
| | Nitric | Hydrogen | | | | Oxidizing | |
| Sample | Acid | Peroxide | Time | Temperature | | Agent | Halogen |
| No. | [wt %] | [wt %] | [sec] | [° C.] | Kind of Solution | [mol/L] | [mol/L] |
| Comparative | 2 | 29 | 30 | 20 | Electrolysis | 0.04 | 0.10 |
| Example 14 | | | | | Sulfuric Acid + | | |
| | | | | | HCl | | |
| Example 36 | Same | Same | Same | 25 | Same as above | Same as | Same |
| | as | as | as | | | above | as |
| | above | above | above | | | | above |
| Example 1 | Same | Same | Same | 50 | Same as above | Same as | Same |
| | as | as | as | | | above | as |
| | above | above | above | | | | above |
| Example 16 | Same | Same | Same | 90 | Same as above | Same as | Same |
| | as | as | as | | | above | as |
| | above | above | above | | | | above |
| Example 17 | Same | Same | Same | 100 | Same as above | Same as | Same |
| | as | as | as | | | above | as |
| | above | above | above | | | | above |
| Comparative | Same | Same | Same | 120 | Same as above | Same as | Same |
| Example 15 | as | as | as | | | above | as |
| | above | above | above | | | | above |

| | Second Solution | | | Evaluation Result | | |
|---|---|---|---|---|---|---|
| | Sulfuric Acid | | | Removal Rate | | |
| Sample | concentration | Temperature | Time | of NiPt | E/R | |
| No. | [wt %] | [° C.] | [sec] | [%] | of Al [Å] | Damage |
| Comparative | 65 | 50 | 50 | 85 | 60 | No |
| Example 14 | | | | | | |
| Example 36 | Same | Same | Same | 95 | 70 | Same |
| | as | as | as | | | as |
| | above | above | above | | | above |
| Example 1 | Same | Same | Same | 100 | 90 | Same |
| | as | as | as | | | as |
| | above | above | above | | | above |
| Example 16 | Same | Same | Same | 100 | 170 | Same |
| | as | as | as | | | as |
| | above | above | above | | | above |
| Example 17 | Same | Same | Same | 100 | 180 | Same |
| | as | as | as | | | as |
| | above | above | above | | | above |
| Comparative | Same | Same | Same | 100 | 300 | Yes |
| Example 15 | as | as | as | | | |
| | above | above | above | | | |

Then, part of the test examples in Table 1 were taken out therefrom based on the kind of the second solution in the second cleaning step, and shown in the following Table 7. The good cleaning effect was attained by using a sulfuric acid solution containing a sulfuric acid-based oxidizing agent and using a halogen acid (salt).

TABLE 7
Kind of Solution

| | First Solution | | | | Second Solution | | |
|---|---|---|---|---|---|---|---|
| | Nitric | Hydrogen | | | | Oxidizing | |
| Sample | Acid | Peroxide | Time | Temperature | | Agent | Halogen |
| No. | [wt %] | [wt %] | [sec] | [° C.] | Kind of Solution | [mol/L] | [mol/L] |
| Example 1 | 2 | 29 | 30 | 50 | Electrolysis Sulfuric | 0.04 | 0.10 |
| | | | | | Acid + HCl | | |
| Example 2 | Same | Same | Same | Same | Electrolysis Sulfuric | Same | Same |
| | as | as | as | as | Acid + NaCl | as | as |
| | above | above | above | above | | above | above |
| Example 3 | Same | Same | Same | Same | Electrolysis Sulfuric | Same | Same |
| | as | as | as | as | Acid + HBr | as | as |
| | above | above | above | above | | above | above |
| Example 4 | Same | Same | Same | Same | Electrolysis Sulfuric | Same | Same |
| | as | as | as | as | Acid + HI | as | as |
| | above | above | above | above | | above | above |
| Example 22 | Same | Same | Same | Same | SPM4:1 + HCl | 0.9 | Same |
| | as | as | as | as | | | as |
| | above | above | above | above | | | above |
| Example 23 | Same | Same | Same | Same | SOM + HCl | 0.002 | Same |
| | as | as | as | as | | | as |
| | above | above | above | above | | | above |

| | Second Solution | | | Evaluation Result | | |
|---|---|---|---|---|---|---|
| | Sulfuric Acid | | | Removal Rate | | |
| Sample | concentration | Temperature | Time | of NiPt | E/R | |
| No. | [wt %] | [° C.] | [sec] | [%] | of Al [Å] | Damage |
| Example 1 | 65 | 50 | 50 | 100 | 90 | No |
| Example 2 | Same | Same | Same | 100 | 90 | Same |
| | as | as | as | | | as |
| | above | above | above | | | above |
| Example 3 | Same | Same | Same | 100 | 90 | Same |
| | as | as | as | | | as |
| | above | above | above | | | above |
| Example 4 | Same | Same | Same | 100 | 90 | Same |
| | as | as | as | | | as |
| | above | above | above | | | above |
| Example 22 | 80 | Same | Same | 100 | 140 | Same |
| | | as | as | | | as |
| | | above | above | | | above |
| Example 23 | 65 | Same | Same | 95 | 80 | Same |
| | | as | as | | | as |
| | | above | above | | | above |

Then, part of the test examples in Table 1 were taken out therefrom based on the difference between the oxidizing agent concentrations in the second cleaning step, and shown in Table 8. Further the following additional test was carried out, and the results are shown in Table 8 similarly.

### Comparative Example 16

The test was carried out under the same condition as in Example 1, except for altering the oxidizing agent concentration of the second solution to 4 mol/L.

As the results, the NiPt removal rate was 100%; the Al etching rate was 200 Å/min; and there was some NiPt silicide damage.

### Example 37

The test was carried out under the same condition as in Example 1, except for altering the oxidizing agent concentration of the second solution to 0.001 mol/L.

As the results, the NiPt removal rate was 95%; the Al etching rate was 70 Å/min; and there was no NiPt silicide damage.

### Example 38

The test was carried out under the same condition as in Example 1, except for altering the oxidizing agent concentration of the second solution to 2 mol/L.

As the results, the NiPt removal rate was 100%; the Al etching rate was 170 Å/min; and there was no NiPt silicide damage.

As is clear from Table 8, the good cleaning effect was attained by setting the oxidizing agent concentration of the second solution to 0.001 mol/L to 2 mol/L, and 0.04 mol/L or higher was more suitable.

TABLE 8
Oxidizing agent Concentration

| | First Solution | | | | Second Solution | | |
|---|---|---|---|---|---|---|---|
| | Nitric | Hydrogen | | | | Oxidizing | |
| Sample | Acid | Peroxide | Time | Temperature | Kind of | Agent | Halogen |
| No. | [wt %] | [wt %] | [sec] | [° C.] | Solution | [mol/L] | [mol/L] |
| Example 37 | 2 | 29 | 30 | 50 | Electrolysis | 0.001 | 0.10 |
| | | | | | Sulfuric Acid + | | |
| | | | | | HCl | | |
| Example 19 | Same | Same | Same | Same | Same | 0.002 | Same |
| | as | as | as | as | as | | as |
| | above | above | above | above | above | | above |
| Example 1 | Same | Same | Same | Same | Same | 0.04 | Same |
| | as | as | as | as | as | | as |
| | above | above | above | above | above | | above |
| Example 18 | Same | Same | Same | Same | Same | 1.80 | Same |
| | as | as | as | as | as | | as |
| | above | above | above | above | above | | above |
| Example 38 | Same | Same | Same | Same | Same | 2 | Same |
| | as | as | as | as | as | | as |
| | above | above | above | above | above | | above |
| Comparative | Same | Same | Same | Same | Same | 4 | Same |
| Example 16 | as | as | as | as | as | | as |
| | above | above | above | above | above | | above |

| | Second Solution | | | Evaluation Result | | |
|---|---|---|---|---|---|---|
| | Sulfuric Acid | | | Removal Rate | | |
| Sample | concentration | Temperature | Time | of NiPt | E/R | |
| No. | [wt %] | [° C.] | [sec] | [%] | of Al [Å] | Damage |
| Example 37 | 65 | 50 | 50 | 95 | 70 | No |
| Example 19 | Same | Same | Same | 95 | 80 | Same |
| | as | as | as | | | as |
| | above | above | above | | | above |
| Example 1 | Same | Same | Same | 100 | 90 | Same |
| | as | as | as | | | as |
| | above | above | above | | | above |
| Example 18 | Same | Same | Same | 100 | 120 | Same |
| | as | as | as | | | as |
| | above | above | above | | | above |
| Example 38 | Same | Same | Same | 100 | 170 | Same |
| | as | as | as | | | as |
| | above | above | above | | | above |
| Comparative | Same | Same | Same | 100 | 200 | Yes |
| Example 16 | as | as | as | | | |
| | above | above | above | | | |

Then, part of the test examples in Table 1 were taken out therefrom based on the difference between the halogen concentrations in the second solution, and shown in Table 9. Further the following additional test was carried out, and the results are shown in Table 9 similarly.

### Comparative Example 17

The test was carried out under the same condition as in Example 1, except for altering the halogen concentration of the second solution to 2.00 mol/L.

As the results, the NiPt removal rate was 100%; the Al etching rate was 200 Å/min; and there was some NiPt silicide damage.

### Example 39

The test was carried out under the same condition as in Example 1, except for altering the halogen concentration of the second solution to 0.001 mol/L.

As the results, the NiPt removal rate was 95%; the Al etching rate was 70 Å/min; and there was no NiPt silicide damage.

As is clear from Table 9, the good cleaning effect was attained by setting the halogen concentration to 0.001 to 1.5 mol/L, and setting the halogen concentration to 0.1 mol/L or higher was more suitable.

TABLE 9
Halogen Concentration

| | First Solution | | | | Second Solution | | |
|---|---|---|---|---|---|---|---|
| | Nitric | Hydrogen | | | | Oxidizing | |
| Sample | Acid | Peroxide | Time | Temperature | | Agent | Halogen |
| No. | [wt %] | [wt %] | [sec] | [° C.] | Kind of Solution | [mol/L] | [mol/L] |
| Example 39 | 2 | 29 | 30 | 50 | Electrolysis | 0.04 | 0.001 |
| | | | | | Sulfuric Acid + | | |
| | | | | | HCl | | |
| Example 20 | Same as | Same as | Same as | Same as | Same as above | Same as | 0.002 |
| | above | above | above | above | | above | |
| Example 1 | Same as | Same as | Same as | Same as | Same as above | Same as | 0.10 |
| | above | above | above | above | | above | |
| Example 21 | Same as | Same as | Same as | Same as | Same as above | Same as | 1.50 |
| | above | above | above | above | | above | |
| Comparative | Same as | Same as | Same as | Same as | Same as above | Same as | 2.00 |
| Example 17 | above | above | above | above | | above | |

| | Second Solution | | | Evaluation Result | | |
|---|---|---|---|---|---|---|
| | Sulfuric Acid | | | Removal Rate | | |
| Sample | concentration | Temperature | Time | of NiPt | E/R | |
| No. | [wt %] | [° C.] | [sec] | [%] | of Al [Å] | Damage |
| Example 39 | 65 | 50 | 50 | 95 | 70 | No |
| Example 20 | Same as | Same as | Same as | 95 | 80 | Same as |
| | above | above | above | | | above |
| Example 1 | Same as | Same as | Same as | 100 | 90 | Same as |
| | above | above | above | | | above |
| Example 21 | Same as | Same as | Same as | 100 | 150 | Same as |
| | above | above | above | | | above |
| Comparative | Same as | Same as | Same as | 100 | 200 | Yes |
| Example 17 | above | above | above | | | |

Then, part of the test examples in Table 1 were taken out therefrom based on the difference between the sulfuric acid concentrations in the second solution, and shown in the following Table 10.

As is clear from the Table, the good cleaning effect was attained by setting the sulfuric acid concentration to 40 to 80% by weight, and setting the sulfuric acid concentration to 65% by weight or higher was more suitable.

TABLE 10
Sulfuric acid Concentration

| | First Solution | | | | Second Solution | | |
|---|---|---|---|---|---|---|---|
| | Nitric | Hydrogen | | | | Oxidizing | |
| Sample | Acid | Peroxide | Time | Temperature | | Agent | Halogen |
| No. | [wt %] | [wt %] | [sec] | [° C.] | Kind of Solution | [mol/L] | [mol/L] |
| Reference | 2 | 29 | 30 | 50 | Electrolysis | 0.04 | 0.10 |
| example 5 | | | | | Sulfuric Acid + | | |
| | | | | | HCl | | |
| Example 5 | Same as | Same as | Same as | Same as | Same as above | Same as | Same as |
| | above | above | above | above | | above | above |
| Example 1 | Same as | Same as | Same as | Same as | Same as above | Same as | Same as |
| | above | above | above | above | | above | above |
| Example 6 | Same as | Same as | Same as | Same as | Same as above | Same as | Same as |
| | above | above | above | above | | above | above |
| Reference | Same as | Same as | Same as | Same as | Same as above | Same as | Same as |
| example 6 | above | above | above | above | | above | above |

| | Second Solution | | | Evaluation Result | | |
|---|---|---|---|---|---|---|
| | Sulfuric Acid | | | Removal Rate | | |
| Sample | concentration | Temperature | Time | of NiPt | E/R | |
| No. | [wt %] | [° C.] | [sec] | [%] | of Al [Å] | Damage |
| Reference | 30 | 50 | 50 | 70 | 60 | No |
| example 5 | | | | | | |
| Example 5 | 40 | Same as | Same as | 95 | 80 | Same as |
| | | above | above | | | above |
| Example 1 | 65 | Same as | Same as | 100 | 90 | Same as |
| | | above | above | | | above |
| Example 6 | 80 | Same as | Same as | 100 | 160 | Same as |
| | | above | above | | | above |
| Reference | 90 | Same as | Same as | 50 | 250 | Same as |
| example 6 | | above | above | | | above |

Then, part of the test examples in Table 1 were taken out therefrom based on the difference between the temperatures of the second solution, and shown in the following Table 11. Further the following additional test was carried out, and the results are shown in Table 11 similarly.

### Example 40

The test was carried out under the same condition as in Example 1, except for altering the temperature of the second solution to 25° C.

As the results, the NiPt removal rate was 95%; the Al etching rate was 55 Å/min; and there was no NiPt silicide damage.

### Example 41

The test was carried out under the same condition as in Example 1, except for altering the temperature of the second solution to 100° C.

As the results, the NiPt removal rate was 100%; the Al etching rate was 180 Å/min; and there was no NiPt silicide damage.

As is clear from Table 11, the good cleaning effect was attained by setting the temperature of the second solution to 25 to 100° C., and 50° C. or higher was more suitable.

TABLE 11
Second cleaning temperature

| | First Solution | | | | Second Solution | | |
|---|---|---|---|---|---|---|---|
| | Nitric | Hydrogen | | | | Oxidizing | |
| Sample | Acid | Peroxide | Time | Temperature | | Agent | Halogen |
| No. | [wt %] | [wt %] | [sec] | [° C.] | Kind of Solution | [mol/L] | [mol/L] |
| Comparative | 2 | 29 | 30 | 50 | Electrolysis | 0.04 | 0.10 |
| Example 7 | | | | | Sulfuric Acid + | | |
| | | | | | HCl | | |
| Example 40 | Same | Same as | Same as | Same as | Same as above | Same as | Same as |
| | as | above | above | above | | above | above |
| | above | | | | | | |
| Example 11 | Same | Same as | Same as | Same as | Same as above | Same as | Same as |
| | as | above | above | above | | above | above |
| | above | | | | | | |
| Example 1 | Same | Same as | Same as | Same as | Same as above | Same as | Same as |
| | as | above | above | above | | above | above |
| | above | | | | | | |
| Example 12 | Same | Same as | Same as | Same as | Same as above | Same as | Same as |
| | as | above | above | above | | above | above |
| | above | | | | | | |
| Example 41 | Same | Same as | Same as | Same as | Same as above | Same as | Same as |
| | as | above | above | above | | above | above |
| | above | | | | | | |
| Comparative | Same | Same as | Same as | Same as | Same as above | Same as | Same as |
| Example 8 | as | above | above | above | | above | above |
| | above | | | | | | |

| | Second Solution | | | Evaluation Result | | |
|---|---|---|---|---|---|---|
| | Sulfuric Acid | | | Removal Rate | | |
| Sample | concentration | Temperature | Time | of NiPt | E/R | |
| No. | [wt %] | [° C.] | [sec] | [%] | of Al [Å] | Damage |
| Comparative | 65 | 20 | 50 | 10 | 50 | No |
| Example 7 | | | | | | |
| Example 40 | Same as | 25 | Same as | 95 | 55 | Same as |
| | above | | above | | | above |
| Example 11 | Same as | 35 | Same as | 95 | 70 | Same as |
| | above | | above | | | above |
| Example 1 | Same as | 50 | Same as | 100 | 90 | Same as |
| | above | | above | | | above |
| Example 12 | Same as | 90 | Same as | 100 | 160 | Same as |
| | above | | above | | | above |
| Example 41 | Same as | 100 | Same as | 100 | 180 | Same as |
| | above | | above | | | above |
| Comparative | Same as | 120 | Same as | 100 | 1000 | Yes |
| Example 8 | above | | above | | | |

### Example A

Cleaning was carried out on (1) a solid wafer having a Pt layer of 5 nm stacked on a silicon substrate, and (2) a solid wafer having a SiO₂ layer of 5 nm stacked on a silicon substrate, respectively, by using the single-substrate type cleaning machine, by bringing the first solution and the second solution into contact with the solid wafers at a rate of 200 ml/min.

The second solution was heated and mixed, and thereafter, made to be supplied to the cleaning machine within 10 min.

The cleaning waste solution after the treatment was subjected to a component analysis using an ICP-MS (inductively coupled plasma mass spectrometer, hereinafter, simply abbreviated to ICP-MS); and the removal ratio of Pt of the substrate was checked using the concentration of Pt in the solution.

With respect to the SiO₂ damage, the presence/absence of damage was checked by observation of a substrate surface by an ellipsometer. The case where the etching rate of SiO₂ was less than 1 nm/min was evaluated as no damage; and the case of 1 nm/min or higher was evaluated as some damage.

According to the present Example, 95% or more of Pt could be removed without damaging SiO₂ and needing much cleaning time. The detail will be described hereinafter.

Part of the test examples in Table 1 were taken out therefrom, based on the presence/absence of the first cleaning, and shown in the following Table 12.

The effect was enhanced by carrying out the first cleaning in which the test object was brought into contact with nitric acid and/or hydrogen peroxide.

TABLE 12
Presence/absence of the first cleaning

| | First Solution | | | | | Second Solution | | | | | | Evaluation Result | |
|---|---|---|---|---|---|---|---|---|---|---|---|---|---|
| | Nitric | Hydrogen | Other | | Tem- | | Oxidizing | | Concentration | Tem- | | Removal | |
| Sample | Acid | Peroxide | acid | Time | perature | Kind | Agent | Halogen | of Sulfuric | perature | Time | Rate | Dam- |
| No. | [wt %] | [wt %] | [wt %] | [sec] | [° C.] | of Solution | [mol/L] | [mol/L] | Acid [wt %] | [° C.] | [sec] | of Pt [%] | age |
| Comparative | — | — | — | — | — | Electrolysis | 0.04 | 0.10 | 65 | 50 | 50 | 20 | No |
| Example A1 | | | | | | Sulfuric | | | | | | | |
| | | | | | | Acid + HCl | | | | | | | |
| Example A1 | 2 | 29 | Same | 30 | 50 | Same | Same as | Same | Same | Same | Same | 100 | Same |
| | | | as | | | as | above | as | as | as | as | | as |
| | | | above | | | above | | above | above | above | above | | above |
| Comparative | — | — | — | — | — | SPM4:1 + | 0.9 | Same | 80 | Same | Same | 50 | Same |
| Example A2 | | | | | | HCl | | as | | as | as | | as |
| | | | | | | | | above | | above | above | | above |
| Example A2 | 2 | 29 | Same | 30 | 50 | Same | Same as | Same | Same | Same | Same | 100 | Same |
| | | | as | | | as | above | as | as | as | as | | as |
| | | | above | | | above | | above | above | above | above | | above |

Then, the evaluations of Examples and Comparative Examples were made with respect to the difference between the nitric acid concentration and the hydrogen peroxide concentration. The test conditions and the evaluation results are shown in Table 13.

As seen in Table 13, the good cleaning result was obtained by setting the nitric acid concentration to 1 to 60% by mass, and the hydrogen peroxide concentration to 2 to 35% by mass.

TABLE 13
The nitric acid Concentration/the hydrogen peroxide Concentration

| | First Solution | | | | | Second Solution | | | | | | Evaluation Result | |
|---|---|---|---|---|---|---|---|---|---|---|---|---|---|
| | Nitric | Hydrogen | Other | | Tem- | | Oxidizing | | Concentration | Tem- | | Removal | |
| Sample | Acid | Peroxide | acid | Time | perature | Kind of | Agent | Halogen | of Sulfuric | perature | Time | Rate | Dam- |
| No. | [wt %] | [wt %] | [wt %] | [sec] | [° C.] | Solution | [mol/L] | [mol/L] | Acid [wt %] | [° C.] | [sec] | of Pt [%] | age |
| Example A1 | 2 | 29 | — | 30 | 50 | Electrolysis | 0.04 | 0.10 | 65 | 50 | 50 | 100 | No |
| | | | | | | Sulfuric | | | | | | | |
| | | | | | | Acid + HCl | | | | | | | |
| Example A3 | 1 | 0 | Same | Same | Same | Same as | Same | Same | Same | Same | Same | 95 | Same |
| | | | as | as | as | above | as | as | as | as | as | | as |
| | | | above | above | above | | above | above | above | above | above | | above |
| Example A4 | 40 | 0 | Same | Same | Same | Same as | Same | Same | Same | Same | Same | 95 | Same |
| | | | as | as | as | above | as | as | as | as | as | | as |
| | | | above | above | above | | above | above | above | above | above | | above |
| Example A5 | 60 | 0 | Same | Same | Same | Same as | Same | Same | Same | Same | Same | 100 | Same |
| | | | as | as | as | above | as | as | as | as | as | | as |
| | | | above | above | above | | above | above | above | above | above | | above |
| Comparative | 62 | 0 | Same | Same | Same | Same as | Same | Same | Same | Same | Same | 100 | Yes |
| Example A3 | | | as | as | as | above | as | as | as | as | as | | |
| | | | above | above | above | | above | above | above | above | above | | |
| Comparative | 0 | 0.1 | Same | Same | Same | Same as | Same | Same | Same | Same | Same | 25 | No |
| Example A4 | | | as | as | as | above | as | as | as | as | as | | |
| | | | above | above | above | | above | above | above | above | above | | |
| Example A6 | 0 | 2 | Same | Same | Same | Same as | Same | Same | Same | Same | Same | 95 | Same |
| | | | as | as | as | above | as | as | as | as | as | | as |
| | | | above | above | above | | above | above | above | above | above | | above |
| Example A7 | 0 | 30 | Same | Same | Same | Same as | Same | Same | Same | Same | Same | 95 | Same |
| | | | as | as | as | above | as | as | as | as | as | | as |
| | | | above | above | above | | above | above | above | above | above | | above |
| Example A8 | 0 | 35 | Same | Same | Same | Same as | Same | Same | Same | Same | Same | 95 | Same |
| | | | as | as | as | above | as | as | as | as | as | | as |
| | | | above | above | above | | above | above | above | above | above | | above |

Then, the evaluation of Examples was carried out based on the kind of the second solution in the second cleaning step. The test conditions and the evaluation results are shown in Table 14.

It is clear from Table 14 that the good cleaning effect was attained by using a sulfuric acid solution containing a sulfuric acid-based oxidizing agent and using a halogen acid (salt).

TABLE 14
Kind of solution

| | First Solution | | | | | Second Solution | | | | | | Evaluation Result | |
|---|---|---|---|---|---|---|---|---|---|---|---|---|---|
| | Nitric | Hydrogen | Other | | Tem- | | Oxidizing | | Concentration | Tem- | | Removal | |
| Sample | Acid | Peroxide | acid | Time | perature | Kind of | Agent | Halogen | of Sulfuric | perature | Time | Rate | Dam- |
| No. | [wt %] | [wt %] | [wt %] | [sec] | [° C.] | Solution | [mol/L] | [mol/L] | Acid [wt %] | [° C.] | [sec] | of Pt [%] | age |
| Example | 2 | 29 | — | 30 | 50 | Electrolysis | 0.04 | 0.10 | 65 | 50 | 50 | 100 | No |
| A1 | | | | | | Sulfuric | | | | | | | |
| | | | | | | Acid + HCl | | | | | | | |
| Example | Same | Same | Same | Same | Same | Electrolysis | Same | Same | Same | Same | Same | 100 | Same |
| A9 | as | as | as | as | as | Sulfuric | as | as | as | as | as | | as |
| | above | above | above | above | above | Acid + NaCl | above | above | above | above | above | | above |
| Example | Same | Same | Same | Same | Same | Electrolysis | Same | Same | Same | Same | Same | 100 | Same |
| A10 | as above | as | as | as | as | Sulfuric | as | as | as | as | as | | as |
| | | above | above | above | above | Acid + HBr | above | above | above | above | above | | above |
| Example | Same | Same | Same | Same | Same | Electrolysis | Same | Same | Same | Same | Same | 100 | Same |
| A11 | as above | as | as | as | as | Sulfuric | as | as | as | as | as | | as |
| | | above | above | above | above | Acid + HI | above | above | above | above | above | | above |
| Example | Same | Same | Same | Same | Same | SPM4:1 + | 0.9 | Same | 80 | Same | Same | 100 | Same |
| A12 | as above | as | as | as | as | HCl | | as | | as | as | | as |
| | | above | above | above | above | | | above | | above | above | | above |
| Example | Same | Same | Same | Same | Same | SOM + | 0.002 | Same | 65 | Same | Same | 95 | Same |
| A13 | as above | as | as | as | as | HCl | | as | | as | as | | as |
| | | above | above | above | above | | | above | | above | above | | above |

Then, the evaluation of Examples and Comparative Examples was carried out based on the difference between oxidizing agent concentrations in the second cleaning step. The test conditions and the evaluation results are shown in Table 15.

It is clear that the good cleaning effect was attained by setting the oxidizing agent concentration to 0.001 mol/L to 2 mol/L, and 0.04 mol/L or higher was more suitable.

TABLE 15
Oxidizing agent Concentration

| | | | | | | Second Solution | | | | | | | |
|---|---|---|---|---|---|---|---|---|---|---|---|---|---|
| | First Solution | | | | | | | | Concen- | | | Evaluation Result | |
| | Nitric | Hydrogen | Other | | Tem- | | Oxidizing | | tration | Tem- | | Removal | |
| Sample | Acid | Peroxide | acid | Time | perature | Kind of | Agent | Halogen | of Sulfuric | perature | Time | Rate | |
| No. | [wt %] | [wt %] | [wt %] | [sec] | [° C.] | Solution | [mol/L] | [mol/L] | Acid [wt %] | [° C.] | [sec] | of Pt [%] | Damage |
| Example | 2 | 29 | — | 30 | 50 | Electrolysis | 0.001 | 0.10 | 65 | 50 | 50 | 95 | No |
| A14 | | | | | | Sulfuric | | | | | | | |
| | | | | | | Acid + HCl | | | | | | | |
| Example | Same as | Same as | Same as | Same | Same as | Same as | 0.002 | Same as | Same as | Same as | Same as | 95 | Same as |
| A15 | above | above | above | as | above | above | | above | above | above | above | | above |
| | | | | above | | | | | | | | | |
| Example | Same as | Same as | Same as | Same | Same as | Same as | 0.04 | Same as | Same as | Same as | Same as | 100 | Same as |
| A1 | above | above | above | as | above | above | | above | above | above | above | | above |
| | | | | above | | | | | | | | | |
| Example | Same as | Same as | Same as | Same | Same as | Same as | 1.80 | Same as | Same as | Same as | Same as | 100 | Same as |
| A16 | above | above | above | as | above | above | | above | above | above | above | | above |
| | | | | above | | | | | | | | | |
| Example | Same as | Same as | Same as | Same | Same as | Same as | 2 | Same as | Same as | Same as | Same as | 100 | Same as |
| A17 | above | above | above | as | above | above | | above | above | above | above | | above |
| | | | | above | | | | | | | | | |
| Compar- | Same as | Same as | Same as | Same | Same as | Same as | 4 | Same as | Same as | Same as | Same as | 100 | Yes |
| ative | above | above | above | as | above | above | | above | above | above | above | | |
| Example | | | | above | | | | | | | | | |
| A5 | | | | | | | | | | | | | |

Then, the evaluation of Examples and Comparative Examples was carried out based on the difference between the halogen concentrations in the second solution. The test conditions and the evaluation results are shown in Table 16.

It is clear from Table 16 that the good cleaning effect was attained by setting the halogen concentration to 0.001 to 1.5 mol/L, and setting the halogen concentration to 0.1 mol/L or higher was more suitable.

TABLE 16
Halogen Concentration

| | | | | | | Second Solution | | | | | | | |
|---|---|---|---|---|---|---|---|---|---|---|---|---|---|
| | First Solution | | | | | | | | Concen- | | | Evaluation Result | |
| | Nitric | Hydrogen | Other | | Tem- | | Oxidizing | | tration | Tem- | | Removal | |
| Sample | Acid | Peroxide | acid | Time | perature | Kind of | Agent | Halogen | of Sulfuric | perature | Time | Rate | |
| No. | [wt %] | [wt %] | [wt %] | [sec] | [° C.] | Solution | [mol/L] | [mol/L] | Acid [wt %] | [° C.] | [sec] | of Pt [%] | Damage |
| Example | 2 | 29 | — | 30 | 50 | Electrolysis | 0.04 | 0.001 | 65 | 50 | 50 | 95 | No |
| A18 | | | | | | Sulfuric | | | | | | | |
| | | | | | | Acid + HCl | | | | | | | |
| Example | Same as | Same as | Same as | Same | Same as | Same as | Same as | 0.002 | Same as | Same as | Same as | 95 | Same as |
| A19 | above | above | above | as | above | above | above | | above | above | above | | above |
| | | | | above | | | | | | | | | |
| Example | Same as | Same as | Same as | Same | Same as | Same as | Same as | 0.10 | Same as | Same as | Same as | 100 | Same as |
| A1 | above | above | above | as | above | above | above | | above | above | above | | above |
| | | | | above | | | | | | | | | |
| Example | Same as | Same as | Same as | Same | Same as | Same as | Same as | 4.00 | Same as | Same as | Same as | 100 | Same as |
| A20 | above | above | above | as | above | above | above | | above | above | above | | above |
| | | | | above | | | | | | | | | |

Then, the evaluation of Examples and Comparative Examples was carried out based on the difference between the sulfuric acid concentrations in the second solution. The test conditions and the evaluation results are shown in Table 17.

It is clear from Table 17 that the good cleaning effect was attained by setting the sulfuric acid concentration to 40 to 80% by weight, and setting the sulfuric acid concentration to 65% by weight or higher was more suitable.

TABLE 17
Sulfuric acid Concentration

| | First Solution | | | | | Second Solution | | | | | | Evaluation Result | |
|---|---|---|---|---|---|---|---|---|---|---|---|---|---|
| | Nitric | Hydrogen | Other | | Tem- | | Oxidizing | | Concentration | Tem- | | Removal | |
| Sample | Acid | Peroxide | acid | Time | perature | Kind of | Agent | Halogen | of Sulfuric | perature | Time | Rate | Dam- |
| No. | [wt %] | [wt %] | [wt %] | [sec] | [° C.] | Solution | [mol/L] | [mol/L] | Acid [wt %] | [° C.] | [sec] | of Pt [%] | age |
| Comparative | 2 | 29 | — | 30 | 50 | Electrolysis | 0.04 | 0.10 | 30 | 50 | 50 | 70 | No |
| Example A6 | | | | | | Sulfuric | | | | | | | |
| | | | | | | Acid + HCl | | | | | | | |
| Example | Same | Same | Same | Same | Same | Same | Same | Same | 40 | Same | Same | 95 | Same |
| A21 | as | as | as | as | as | as | as | as | | as | as | | as |
| | above | above | above | above | above | above | above | above | | above | above | | above |
| Example A1 | Same | Same | Same | Same | Same | Same | Same | Same | 65 | Same | Same | 100 | Same |
| | as | as | as | as | as | as | as | as | | as | as | | as |
| | above | above | above | above | above | above | above | above | | above | above | | above |
| Example | Same | Same | Same | Same | Same | Same | Same | Same | 80 | Same | Same | 100 | Same |
| A22 | as | as | as | as | as | as | as | as | | as | as | | as |
| | above | above | above | above | above | above | above | above | | above | above | | above |
| Comparative | Same | Same | Same | Same | Same | Same | Same | Same | 90 | Same | Same | 50 | Same |
| Example A7 | as | as | as | as | as | as | as | as | | as | as | | as |
| | above | above | above | above | above | above | above | above | | above | above | | above |

Then, the evaluation of Examples and Comparative Examples was carried out based on the difference between the temperatures of the second solution. The test conditions and the evaluation results are shown in Table 18.

It is clear from Table 18 that the good cleaning effect was attained by setting the temperature of the second solution to 25 to 100° C., and 50° C. or higher was more suitable.

TABLE 18
Second cleaning temperature

| | | | | | | Second Solution | | | | | | | |
|---|---|---|---|---|---|---|---|---|---|---|---|---|---|
| | First Solution | | | | | | | | Concen- | | | Evaluation Result | |
| | Nitric | Hydrogen | Other | | Tem- | | Oxidizing | | tration | Tem- | | Removal | |
| Sample | Acid | Peroxide | acid | Time | perature | Kind of | Agent | Halogen | of Sulfuric | perature | Time | Rate | |
| No. | [wt %] | [wt %] | [wt %] | [sec] | [° C.] | Solution | [mol/L] | [mol/L] | Acid [wt %] | [° C.] | [sec] | Of Pt [%] | Damage |
| Comparative | 2 | 29 | — | 30 | 50 | Electrolysis | 0.04 | 0.10 | 65 | 20 | 50 | 10 | No |
| Example A8 | | | | | | Sulfuric | | | | | | | |
| | | | | | | Acid + HCl | | | | | | | |
| Example | Same as | Same as | Same as | Same | Same | Same as | Same as | Same as | Same as | 35 | Same | 95 | Same as |
| A23 | above | above | above | as | as | above | above | above | above | | as | | above |
| | | | | above | above | | | | | | above | | |
| Example | Same as | Same as | Same as | Same | Same | Same as | Same as | Same as | Same as | 35 | Same | 95 | Same as |
| A24 | above | above | above | as | as | above | above | above | above | | as | | above |
| | | | | above | above | | | | | | above | | |
| Example A1 | Same as | Same as | Same as | Same | Same | Same as | Same as | Same as | Same as | 50 | Same | 100 | Same as |
| | above | above | above | as | as | above | above | above | above | | as | | above |
| | | | | above | above | | | | | | above | | |
| Example | Same as | Same as | Same as | Same | Same | Same as | Same as | Same as | Same as | 90 | Same | 100 | Same as |
| A25 | above | above | above | as | as | above | above | above | above | | as | | above |
| | | | | above | above | | | | | | above | | |
| Example | Same as | Same as | Same as | Same | Same | Same as | Same as | Same as | Same as | 100 | Same | 100 | Same as |
| A26 | above | above | above | as | as | above | above | above | above | | as | | above |
| | | | | above | above | | | | | | above | | |
| Comparative | Same as | Same as | Same as | Same | Same | Same as | Same as | Same as | Same as | 120 | Same | 100 | Yes |
| Example A9 | above | above | above | as | as | above | above | above | above | | as | | |
| | | | | above | above | | | | | | above | | |

Here, the cleaning objects are not limited to ones evaluated in the above Examples. For example, under the same conditions as in the above Examples, when Pt on a Si substrate is removed, the Pt can effectively be removed without damaging SiO₂; when NiPt on a Si substrate is removed, the NiPt can effectively be removed without damaging SiNiPt and Al; when Pt on a SiC substrate is removed, the Pt can effectively be removed without damaging SiC; and when Pt on a SiGe substrate is removed, the Pt can effectively be removed without damaging SiGe.

### REFERENCE SIGNS LIST

1 SEMICONDUCTOR SUBSTRATE CLEANING SYSTEM
2 SINGLE-SUBSTRATE TYPE CLEANING MACHINE
3 NITRIC ACID SOLUTION STORAGE TANK
4 HYDROGEN PEROXIDE SOLUTION STORAGE TANK
5 SULFURIC ACID SOLUTION STORAGE TANK
6 HALIDE SOLUTION STORAGE TANK
10 NITRIC ACID SOLUTION SUPPLY LINE
11 LIQUID FEED PUMP
12 HYDROGEN PEROXIDE SOLUTION SUPPLY LINE
13 LIQUID FEED PUMP
14 FIRST SOLUTION COMMON LIQUID FEED LINE
15 HEATER
16 DELIVERY NOZZLE
20 SULFURIC ACID SOLUTION SUPPLY LINE
21 LIQUID FEED PUMP
22 HALIDE SOLUTION SUPPLY LINE
23 LIQUID FEED PUMP

1. A method for cleaning a semiconductor substrate to remove platinum and/or a platinum alloy from the semiconductor substrate having a layer having Si as a constituting element thereof, the method comprising:
a first cleaning step of bringing the semiconductor substrate into contact with a first solution containing nitric acid and/or hydrogen peroxide as main solutes to thereby clean the semiconductor substrate; and
a second cleaning step of bringing the semiconductor substrate having undergone the first cleaning step into contact with a second solution containing an oxidizing agent-containing sulfuric acid solution and a halide and having a temperature of 25 to 100° C., to thereby clean the semiconductor substrate.

2. The method for cleaning a semiconductor substrate according to claim 1, wherein the semiconductor substrate is any one of a semiconductor substrate having an insulating film constituted of a Si compound, a semiconductor substrate constituted of Si or a Si compound semiconductor, and a semiconductor substrate having a silicide film.

3. The method for cleaning a semiconductor substrate according to claim 1, wherein the semiconductor substrate has a silicide film containing platinum formed thereon.

4. The method for cleaning a semiconductor substrate according to claim 1, wherein the semiconductor substrate has Al present thereon.

5. The method for cleaning a semiconductor substrate according to claim 1, wherein the semiconductor substrate has SiO₂ platinum and/or a platinum alloy and SiO₂ exposed thereon.

6. The method for cleaning a semiconductor substrate according to claim 1, wherein the semiconductor substrate is a SiC substrate having platinum and/or a platinum alloy exposed thereon.

7. The method for cleaning a semiconductor substrate according to claim 1, wherein the semiconductor substrate is a SiGe substrate having platinum and/or a platinum alloy exposed thereon.

8. The method for cleaning a semiconductor substrate according to claim 1, wherein the halide comprises one or more selected from the group consisting of chlorides, bromides and iodides.

9. The method for cleaning a semiconductor substrate according to claim 1, wherein the first solution contains 80% or more in mass ratio of nitric acid and/or hydrogen peroxide with respect to the whole solutes.

10. The method for cleaning a semiconductor substrate according to claim 1, wherein the first solution contains nitric acid, and has a nitric acid concentration of 1 to 60% by mass.

11. The method for cleaning a semiconductor substrate according to claim 1, wherein the first solution contains hydrogen peroxide, and has a hydrogen peroxide concentration of 1 to 35% by mass.

12. The method for cleaning a semiconductor substrate according to claim 11, wherein the hydrogen peroxide concentration is 2 to 35% by mass.

13. The method for cleaning a semiconductor substrate according to claim 1, wherein the first solution in the first cleaning step has a temperature of 25 to 100° C.

14. The method for cleaning a semiconductor substrate according to claim 1, wherein the second solution has a sulfuric acid concentration of 40 to 80% by mass.

15. The method for cleaning a semiconductor substrate according to claim 1, wherein the second solution has an oxidizing agent concentration of 0.001 to 2 mol/L.

16. The method for cleaning a semiconductor substrate according to claim 1, wherein the oxidizing agent is persulfuric acid.

17. The method for cleaning a semiconductor substrate according to claim 1, wherein the oxidizing agent-containing sulfuric acid solution of the second solution is one or more selected from the group consisting of sulfuric acid electrolytic solutions, mixed solutions of sulfuric acid and hydrogen peroxide, and mixed solutions of sulfuric acid and ozone.

18. The method for cleaning a semiconductor substrate according to claim 1, further comprising, before the second cleaning step, a first solution discharge step of discharging the first solution from the semiconductor substrate having undergone the first cleaning step.

19. A system for cleaning a semiconductor substrate, comprising:
a cleaning section carrying out cleaning to remove platinum and/or a platinum alloy from a semiconductor substrate having a layer having Si as a constituting element thereof;
a first solution-accommodating section accommodating a first solution containing nitric acid and/or hydrogen peroxide as main solutes;
a second solution-accommodating section accommodating a second solution containing an oxidizing agent-containing sulfuric acid solution and a halide;
a first solution supply line having one end thereof connected to the first solution accommodating section and the other end thereof connected to the cleaning section, and supplying the first solution from the first solution-accommodating section to the cleaning section;
a second solution supply line having one end thereof connected to the second solution-accommodating section and the other end thereof connected to the cleaning section, and supplying the second solution from the second solution-accommodating section to the cleaning section;
a first solution temperature-regulating section provided on the first solution supply line and regulating the solution temperature of the first solution supplied to the cleaning section through the first solution supply line at a predetermined temperature;
a first solution delivery section connected to the end on the cleaning section side of the first solution supply line and delivering the first solution in the cleaning section to thereby bring the first solution into contact with the semiconductor substrate; and
a second solution delivery section connected to the end on the cleaning section side of the second solution supply line and delivering the second solution in the cleaning section to thereby bring the second solution into contact with the semiconductor substrate.

20. The system for cleaning a semiconductor substrate according to claim 19, further comprises a cleaning control section controlling the supplies of the first solution and the second solution to carry out the first cleaning step of carrying out cleaning of the semiconductor substrate by using the first solution in the cleaning section and to carry out, after the first cleaning step, the second cleaning step of carrying out cleaning of the semiconductor substrate by using the second solution in the cleaning section.
